(19) United States
(12) Patent Application Publication
(10) Pub. No.: US 2026/0143746 A1
(43) Pub. Date: May 21, 2026

(54) ANGLED CONTACT CONFIGURATION FOR STACKED TRANSISTOR STRUCTURES

(71) Applicant: International Business Machines Corporation, Armonk, NY (US)

(72) Inventors: Debarghya Sarkar, Latham, NY (US); Ruilong Xie, Niskayuna, NY (US); Albert Manhee Chu, Nashua, NH (US); Shay Reboh, Guilderland, NY (US); Oleg Gluschenkov, Tannersville, NY (US); Kisik Choi, Watervliet, NY (US)

(21) Appl. No.: 18/950,603

(22) Filed: Nov. 18, 2024

(51) Int. Cl. H01L 29/417; H01L 21/822; H01L 21/8238; H01L 27/092; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 84/0186; H10D 84/038; H10D 84/856; H10D 88/01

(57) ABSTRACT

A semiconductor device includes a first transistor including a first set of one or more channels and a second transistor vertically stacked over the first transistor, where the second transistor includes a second set of one or more channels. The semiconductor device also includes a first contact extending from a first side of the semiconductor structure to a first source/drain region of the first transistor, and a second contact extending from the first side of the semiconductor structure to a second source/drain region of the second transistor, where the second contact is angled away from the first contact.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments described herein provide techniques for forming an angled contact configuration for stacked transistor structures.

In an illustrative embodiment, a semiconductor device includes a first transistor including a first set of one or more channels and a second transistor vertically stacked over the first transistor, where the second transistor includes a second set of one or more channels. The semiconductor device also includes a first contact extending from a first side of the semiconductor structure to a first source/drain region of the first transistor, and a second contact extending from the first side of the semiconductor structure to a second source/drain region of the second transistor, where the second contact is angled away from the first contact.

In another embodiment, a semiconductor device includes a first transistor comprising a first set of one or more channels, a second transistor vertically stacked over the first transistor, the second transistor comprising a second set of one or more channels, where the second set of channels of the second transistor is horizontally offset from the first set of channels of the first transistor. The semiconductor device also includes a first contact extending from a first side of the semiconductor structure to a first source/drain region of the first transistor, and a second contact extending from the first side of the semiconductor structure to a second source/drain region of the second transistor, where the second contact is angled away from the first contact.

In yet another embodiment, a method includes forming a first transistor of a semiconductor structure comprising a first set of one or more channels, forming a second transistor vertically stacked over the first transistor, the second transistor comprising a second set of one or more channels, and forming a first contact extending from a first side of the semiconductor structure to a first source/drain region of the first transistor. The method also includes forming a second contact extending from the first side of the semiconductor structure to a second source/drain region of the second transistor, where the second contact is angled away from the first contact.

These and other features and advantages of embodiments described herein will become more apparent from the accompanying drawings and the following detailed description.

### BRIEF DESCRIPTION OF THE DRAWINGS

FIG. 1A depicts a first cross-sectional view of a semiconductor structure following formation of a bottom dummy gate layer for bottom transistors of a stacked transistor structure, formation of inner spacers, formation of a first placeholder layer for a first backside contact, and formation of source/drain regions for the bottom transistors of the stacked transistor structure, according to an embodiment.

FIG. 1B depicts a second cross-sectional view of the semiconductor structure following the formation of the bottom dummy gate layer for the bottom transistors of the stacked transistor structure, the formation of the inner spacers, the formation of the first placeholder layer, and the formation of the source/drain regions for the bottom transistors of the stacked transistor structure, according to an embodiment.

FIG. 1C depicts a third cross-sectional view of the semiconductor structure following the formation of the bottom dummy gate layer for the bottom transistors of the stacked transistor structure, the formation of the inner spacers, the formation of the first placeholder layer, and the formation of the source/drain regions for the bottom transistors of the stacked transistor structure, according to an embodiment.

FIG. 1D depicts a fourth cross-sectional view of the semiconductor structure following the formation of the bottom dummy gate layer for the bottom transistors of the stacked transistor structure, the formation of the inner spacers, the formation of the first placeholder layer, and the formation of the source/drain regions for the bottom transistors of the stacked transistor structure, according to an embodiment.

FIG. 1E depicts a top-down view illustrating where the first, second, third, and fourth cross-sectional views of FIGS. 1A-1D are taken, according to an embodiment.

FIG. 2A depicts a first cross-sectional view of the structure of FIGS. 1A-1D following removal of the bottom dummy gate layer, according to an embodiment.

FIG. 2B depicts a second cross-sectional view of the structure of FIGS. 1A-1D following the removal of the bottom dummy gate layer, according to an embodiment.

FIG. 2C depicts a third cross-sectional view of the structure of FIGS. 1A-1D following the removal of the bottom dummy gate layer, according to an embodiment.

FIG. 2D depicts a fourth cross-sectional view of the structure of FIGS. 1A-1D following the removal of the bottom dummy gate layer, according to an embodiment.

FIG. 3A depicts a first cross-sectional view of the structure of FIGS. 2A-2D following growth of a conformal epitaxial layer to define a gate extension for the bottom transistors of the stacked transistor structure, according to an embodiment.

FIG. 3B depicts a second cross-sectional view of the structure of FIGS. 2A-2D following the growth of the conformal epitaxial layer to define the gate extension for the bottom transistors of the stacked transistor structure, according to an embodiment.

FIG. 3C depicts a third cross-sectional view of the structure of FIGS. 2A-2D following the growth of the conformal epitaxial layer to define the gate extension for the bottom transistors of the stacked transistor structure, according to an embodiment.

FIG. 3D depicts a fourth cross-sectional view of the structure of FIGS. 2A-2D following the growth of the conformal epitaxial layer to define the gate extension for the bottom transistors of the stacked transistor structure, according to an embodiment.

FIG. 4A depicts a first cross-sectional view of the structure of FIGS. 3A-3D following formation of a self-aligned gate isolation layer, according to an embodiment.

FIG. 4B depicts a second cross-sectional view of the structure of FIGS. 3A-3D following the formation of the self-aligned gate isolation layer, according to an embodiment.

FIG. 4C depicts a third cross-sectional view of the structure of FIGS. 3A-3D following the formation of the self-aligned gate isolation layer, according to an embodiment.

FIG. 4D depicts a fourth cross-sectional view of the structure of FIGS. 3A-3D following the formation of the self-aligned gate isolation layer, according to an embodiment.

FIG. 5A depicts a first cross-sectional view of the structure of FIGS. 4A-4D following formation of a gate stack for the bottom transistors of the stacked transistor structure, according to an embodiment.

FIG. 5B depicts a second cross-sectional view of the structure of FIGS. 4A-4D following the formation of the gate stack for the bottom transistors of the stacked transistor structure, according to an embodiment.

FIG. 5C depicts a third cross-sectional view of the structure of FIGS. 4A-4D following the formation of the gate stack for the bottom transistors of the stacked transistor structure, according to an embodiment.

FIG. 5D depicts a fourth cross-sectional view of the structure of FIGS. 4A-4D following the formation of the gate stack for the bottom transistors of the stacked transistor structure, according to an embodiment.

FIG. 6A depicts a first cross-sectional view of the structure of FIGS. 5A-5D following patterning of an organic planarization layer, according to an embodiment.

FIG. 6B depicts a second cross-sectional view of the structure of FIGS. 5A-5D following the patterning of the organic planarization layer, according to an embodiment.

FIG. 6C depicts a third cross-sectional view of the structure of FIGS. 5A-5D following the patterning of the organic planarization layer, according to an embodiment.

FIG. 6D depicts a fourth cross-sectional view of the structure of FIGS. 5A-5D following the patterning of the organic planarization layer, according to an embodiment.

FIG. 7A depicts a first cross-sectional view of the structure of FIGS. 6A-6D following selective etching of the interlayer dielectric layer and the shallow trench isolation regions with an angled etch, according to an embodiment.

FIG. 7B depicts a second cross-sectional view of the structure of FIGS. 6A-6D following the selective etching of the interlayer dielectric layer and the shallow trench isolation regions with the angled etch, according to an embodiment.

FIG. 7C depicts a third cross-sectional view of the structure of FIGS. 6A-6D following the selective etching of the interlayer dielectric layer and the shallow trench isolation regions with the angled etch, according to an embodiment.

FIG. 7D depicts a fourth cross-sectional view of the structure of FIGS. 6A-6D following the selective etching of the interlayer dielectric layer and the shallow trench isolation regions with the angled etch, according to an embodiment.

FIG. 8A depicts a first cross-sectional view of the structure of FIGS. 7A-7D following lateral etching of the spacer layer and the shallow trench isolation regions, and formation of dielectric spacer layers and a second placeholder layer for a second backside contact, according to an embodiment.

FIG. 8B depicts a second cross-sectional view of the structure of FIGS. 7A-7D following lateral etching of the spacer layer and the shallow trench isolation regions, and formation of the dielectric spacer layers and the second placeholder layer, according to an embodiment.

FIG. 8C depicts a third cross-sectional view of the structure of FIGS. 7A-7D following lateral etching of the spacer layer and the shallow trench isolation regions, and formation of the dielectric spacer layers and the second placeholder layer, according to an embodiment.

FIG. 8D depicts a fourth cross-sectional view of the structure of FIGS. 7A-7D following lateral etching of the spacer layer and the shallow trench isolation regions, and formation of the dielectric spacer layers and the second placeholder layer, according to an embodiment.

FIG. 9A depicts a first cross-sectional view of the structure of FIGS. 8A-8D following bonding of another nanosheet stack including nanosheet channel layers for top transistors of the stacked transistor structure, according to an embodiment.

FIG. 9B depicts a second cross-sectional view of the structure of FIGS. 8A-8D following the bonding of the other nanosheet stack including the nanosheet channel layers for the top transistors of the stacked transistor structure, according to an embodiment.

FIG. 9C depicts a third cross-sectional view of the structure of FIGS. 8A-8D following the bonding of the other nanosheet stack including the nanosheet channel layers for the top transistors of the stacked transistor structure, according to an embodiment.

FIG. 9D depicts a fourth cross-sectional view of the structure of FIGS. 8A-8D following the bonding of the other nanosheet stack including the nanosheet channel layers for the top transistors of the stacked transistor structure, according to an embodiment.

FIG. 10A depicts a first cross-sectional view of the structure of FIGS. 9A-9D following formation of a top dummy gate layer, a spacer layer, source/drain regions for the top transistors of the stacked transistor structure, and an interlayer dielectric layer, according to an embodiment.

FIG. 10B depicts a second cross-sectional view of the structure of FIGS. 9A-9D following the formation of the top dummy gate layer, the spacer layer, the source/drain regions for the top transistors of the stacked transistor structure, and the interlayer dielectric layer, according to an embodiment.

FIG. 10C depicts a third cross-sectional view of the structure of FIGS. 9A-9D following the formation of the top dummy gate layer, the spacer layer, the source/drain regions for the top transistors of the stacked transistor structure, and the interlayer dielectric layer, according to an embodiment.

FIG. 10D depicts a fourth cross-sectional view of the structure of FIGS. 9A-9D following the formation of the top dummy gate layer, the spacer layer, the source/drain regions for the top transistors of the stacked transistor structure, and the interlayer dielectric layer, according to an embodiment.

FIG. 11A depicts a first cross-sectional view of the structure of FIGS. 10A-10D following formation of a gate stack for the top transistors, a gate cut for the top transistors, formation of dielectric spacer layers, frontside interconnects, and back-end-of-line regions, and following bonding to a carrier wafer, according to an embodiment.

FIG. 11B depicts a second cross-sectional view of the structure of FIGS. 10A-10D following the formation of the gate stack for the top transistors, the gate cut for the top transistors, the formation of the dielectric spacer layers, the frontside interconnects, and the back-end-of-line regions, and following the bonding to the carrier wafer, according to an embodiment.

FIG. 11C depicts a third cross-sectional view of the structure of FIGS. 10A-10D following the formation of the gate stack for the top transistors, the gate cut for the top transistors, the formation of the dielectric spacer layers, the frontside interconnects, and the back-end-of-line regions, and following the bonding to the carrier wafer, according to an embodiment.

FIG. 11D depicts a fourth cross-sectional view of the structure of FIGS. 10A-10D following the formation of the gate stack for the top transistors, the gate cut for the top transistors, the formation of the dielectric spacer layers, the frontside interconnects, and the back-end-of-line regions, and following the bonding to the carrier wafer, according to an embodiment.

FIG. 12A depicts a first cross-sectional view of the structure of FIGS. 11A-11D following removal of the substrates and etch stop layer from the backside, formation of a backside interlayer dielectric layer, and following a planarization process, according to an embodiment.

FIG. 12B depicts a second cross-sectional view of the structure of FIGS. 11A-11D following removal of the substrates and etch stop layer from the backside, formation of the backside interlayer dielectric layer, and following the planarization process, according to an embodiment.

FIG. 12C depicts a third cross-sectional view of the structure of FIGS. 11A-11D following removal of the substrates and etch stop layer from the backside, formation of the backside interlayer dielectric layer, and following the planarization process, according to an embodiment.

FIG. 12D depicts a fourth cross-sectional view of the structure of FIGS. 11A-11D following removal of the substrates and etch stop layer from the backside, formation of the backside interlayer dielectric layer, and following the planarization process, according to an embodiment.

FIG. 13A depicts a first cross-sectional view of the structure of FIGS. 12A-12D following selective removal of the second backside contact placeholder layer and formation of the second backside contact, according to an embodiment.

FIG. 13B depicts a second cross-sectional view of the structure of FIGS. 12A-12D following the selective removal of the second backside contact placeholder layer and the formation of the second backside contact, according to an embodiment.

FIG. 13C depicts a third cross-sectional view of the structure of FIGS. 12A-12D following the selective removal of the second backside contact placeholder layer and the formation of the second backside contact, according to an embodiment.

FIG. 13D depicts a fourth cross-sectional view of the structure of FIGS. 12A-12D following the selective removal of the second backside contact placeholder layer and the formation of the second backside contact, according to an embodiment.

FIG. 14A depicts a first cross-sectional view of the structure of FIGS. 13A-13D following selective removal of the first backside contact placeholder layer and formation of the first backside contact, according to an embodiment.

FIG. 14B depicts a second cross-sectional view of the structure of FIGS. 13A-13D following selective removal of the first backside contact placeholder layer and formation of the first backside contact, according to an embodiment.

FIG. 14C depicts a third cross-sectional view of the structure of FIGS. 13A-13D following selective removal of the first backside contact placeholder layer and formation of the first backside contact, according to an embodiment.

FIG. 14D depicts a fourth cross-sectional view of the structure of FIGS. 13A-13D following selective removal of the first backside contact placeholder layer and formation of the first backside contact, according to an embodiment.

FIG. 15A depicts a first cross-sectional view of the structure of FIGS. 14A-14D following formation of backside interconnects, according to an embodiment.

FIG. 15B depicts a second cross-sectional view of the structure of FIGS. 14A-14D following the formation of the backside interconnects, according to an embodiment.

FIG. 15C depicts a third cross-sectional view of the structure of FIGS. 14A-14D following the formation of the backside interconnects, according to an embodiment.

FIG. 15D depicts a fourth cross-sectional view of the structure of FIGS. 14A-14D following the formation of the backside interconnects, according to an embodiment.

### DETAILED DESCRIPTION

Illustrative embodiments may be described herein in the context of illustrative methods for forming backside contacts for stacked transistor structures with shifted channels, along with illustrative apparatus, systems and devices formed using such methods. However, it is to be understood that embodiments are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the area of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm node and beyond. A general process flow for formation of a nanosheet stack involves removing sacrificial layers, which may be formed of silicon germanium (SiGe), between sheets of channel material, which may be formed of silicon (Si).

For continued scaling and area improvement, stacked transistor structures may be used. A stacked transistor structure may include multiple transistors stacked over one another vertically. With stacked transistor structures, for example, vias which extend between the frontside and the backside may have a high aspect ratio. The formation of high aspect ratio vias, however, presents various process challenges.

Stacked transistor structures may utilize sequential integration fabrication processes. Sequential integration includes forming “bottom” (also referred to as “lower”) transistors of a stacked transistor structure, followed by wafer bonding and formation of “top” (also referred to as “upper”) transistors of the stacked transistor structure. The bottom and top transistors of the stacked transistor structure may also be referred to as being different “tiers” or “levels” of the stacked transistor structure (e.g., where the bottom transistors are a first tier or level of the stacked transistor structure and the top transistors are a second tier or level of the stacked transistor structure). Sequential integration fabrication processes provide various advantages relative to monolithic fabrication processes. For example, sequential integration allows for: an increased effective width (Weff) with the same device footprint; increasing the number of channels (e.g., nanosheet channels); and further critical dimension (CD) scaling. Since the top and bottom tiers are integrated separately, sequential integration allows for unique transistor architectures (e.g., shifted, staggered, etc.), split gate schemes, multiple threshold voltage (multi-Vt) replacement metal gate (RMG) learning from nanosheets, channel engineering for the top and bottom tiers (e.g., mobility), and reduced process complexity.

Stacked transistor structures may use different transistor architectures, such as a “stepped” architecture (e.g., where nanosheet channels for the top transistors of a stacked transistor structure are narrower than nanosheet channels for the bottom transistors of the stacked transistor structure) and an “aligned” architecture (e.g., where nanosheet channels for the top and bottom transistors of a stacked transistor structure have the same size and are aligned with one another). Wafer bonding approaches used in sequential integration fabrication processes further allow for a “shifted” architecture (e.g., where the active regions or nanosheet channels for the top and bottom transistors of the stacked transistor structure are offset from one another) and a “staggered” architecture (e.g., where cell or device boundaries for the top and bottom transistors of the stacked transistor structure are offset from one another). Both the shifted and staggered architectures provide for lower aspect ratio (AR) for middle-of-line (MOL) contact formation, and also provide a Weff benefit with respect to the aligned active regions.

In some illustrative embodiments, a stacked transistor structure includes top and bottom transistors with aligned cell boundaries (e.g., within lithography tolerance), where the top and bottom transistors in the stacked transistor structure have gate-all-around (GAA) channels (e.g., nanosheet channels) which are horizontally shifted relative to one another along the gate axis.

Contact formation for such stacked transistor structures provides various technical challenges, including that backside contacts to the source/drain regions for the top and bottom transistors can easily short to one another and/or gate regions. Further, backside power rails in a backside power delivery network (BSPDN) may be crowded, such that the backside power rails can short with each other.

Embodiments described herein provide backside contact configuration for stacked transistor structures with shifted channels which advantageously solve critical issues related to forming connections for stacked transistor structures. For example, one or more embodiments can help prevent shorts between a backside contact for a top source/drain region and a backside contact for a bottom source/drain region, thereby avoiding the need for more complex back-end-of-line (BEOL) patterning schemes.

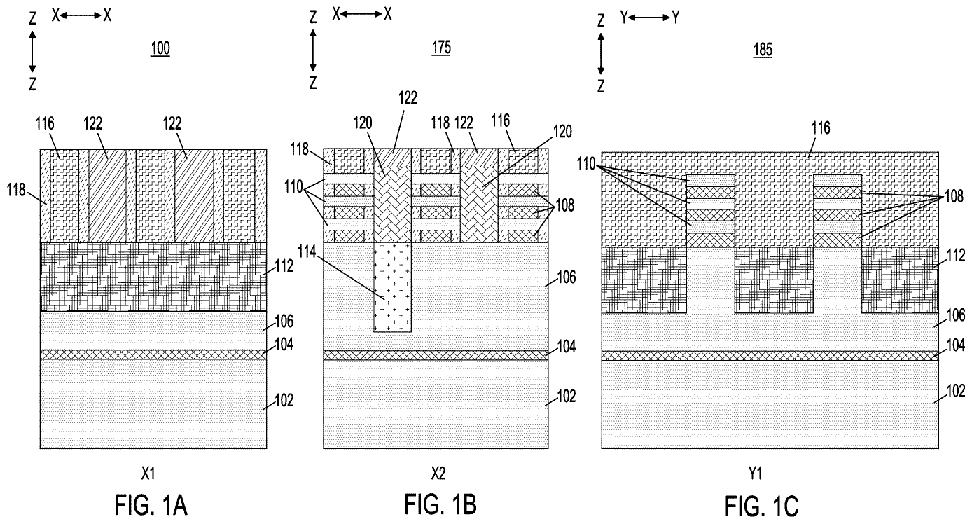

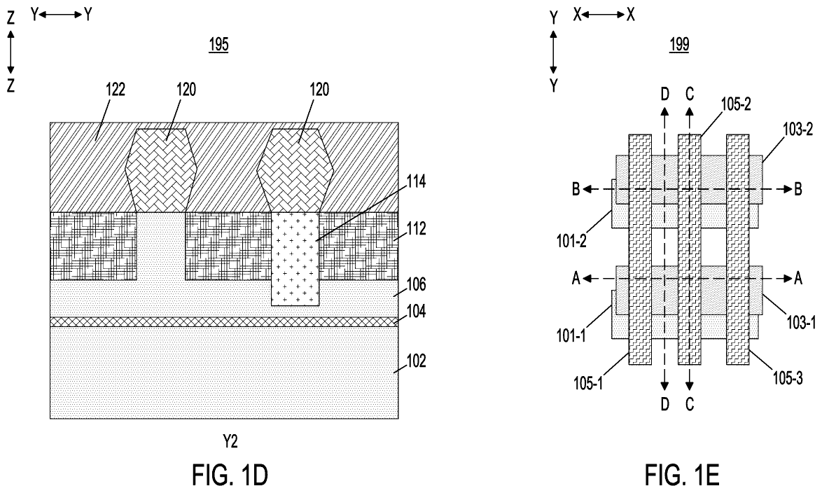

FIGS. 1A-15D show a process flow for forming an angled contact configuration for stacked transistor structures.

FIGS. 1A-1E show different views of a semiconductor structure. FIGS. 1A-1D show cross-sectional views 100, 175, 185, and 195, and FIG. 1E shows a top-down view 199 illustrating where the cross-sectional views 100, 175, 185, and 195 of FIGS. 1A-1D are taken. FIG. 1E shows active (e.g., channel) regions 101-1 and 101-2 for bottom transistors of a stacked transistor structure, active (e.g., channel) regions 103-1 and 103-2 for top transistors of the stacked transistor structure, and gate regions 105-1, 105-2, and 105-3. The cross-sectional view 100 of FIG. 1A is taken along the line A-A shown in the top-down view 199 of FIG. 1E (e.g., across the gate regions 105-1, 105-2, and 105-3 and along the active region 103-1). The cross-sectional view 175 of FIG. 1B is taken along the line B-B shown in the top-down view 199 of FIG. 1E (e.g., across the gate regions 105-1, 105-2, and 105-3 and along the active regions 101-2 and 103-2). The cross-sectional view 185 of FIG. 1C is taken along the line C-C shown in the top-down view 199 of FIG. 1E (e.g., across the active regions 101-1, 101-2, 103-1, and 103-2 and along the gate region 105-2). The cross-sectional view 195 of FIG. 1D is taken along the line D-D shown in the top-down view 199 of FIG. 1E (e.g., across the active regions 101-1, 101-2, 103-1, and 103-2 and between gate regions 105-1 and 105-2).

The semiconductor structure shown in FIGS. 1A-1D includes a substrate 102, an etch stop layer 104, a substrate 106, a nanosheet stack comprising alternating sacrificial layers 108 and nanosheet channel layers 110, shallow trench isolation (STI) regions 112, a backside contact placeholder layer 114, a bottom dummy gate layer 116 for bottom transistors of a stacked transistor structure, a spacer layer 118, source/drain regions 120 for the bottom transistors of the stacked transistor structure, and an interlayer dielectric (ILD) layer 122.

The substrates 102 and 106 may be formed of any suitable semiconductor material, including various silicon-containing materials such as silicon (Si), silicon germanium (SiGe), silicon germanium carbide (SiGeC), silicon carbide (SiC), or multi-layers thereof. Although silicon is the predominantly used semiconductor material in wafer fabrication, alternative semiconductor materials can be employed as additional layers such as, but not limited to, germanium (Ge), gallium arsenide (GaAs), gallium nitride (GaN), SiGe, cadmium telluride (CdTe), zinc selenide (ZnSe), etc. The substrates 102 and 106 may have respective heights (in direction Z) and widths (in directions X/Y) that vary as needed based on the type of structures to be formed.

The etch stop layer 104 may comprise a buried oxide (BOX) layer formed of silicon germanium (SiGe), silicon dioxide (SiO2), or another suitable material such as a III-V semiconductor epitaxial layer. The etch stop layer 104 may have a height (in direction Z) in the range of 10 to 50 nm.

The sacrificial layers 108 may be formed of SiGe. In some embodiments, each of the sacrificial layers 108 may have a thickness (in direction Z) in the range of 5 to 15 nm.

In some embodiments, both the etch stop layer 104 and the sacrificial layers 108 are formed of SiGe, with a germanium (Ge) concentration in the range of 20-40%. It should be noted, however, that this is not a requirement, and that the etch stop layer 104 and the sacrificial layers 108 may be formed of different materials or both may be formed of SiGe but with different percentages of Ge.

The nanosheet channel layers 110 provide channels for the bottom transistors (e.g., nanosheet transistors) of the stacked transistor structure. The nanosheet channel layers 110 may be formed of Si or another suitable material (such as a material similar to that used for the substrates 102 and 106). In some embodiments, each of the nanosheet channel layers 110 may have a thickness (in direction Z) in the range of 5 to 15 nm.

The STI regions 112 may be formed of a dielectric material such as silicon dioxide (SiO2), silicon oxycarbide (SiOC), silicon oxynitride (SiON), etc. In some embodiments, the STI regions 112 may have a height (in direction Z) in the range of 10 to 200 nm.

The backside contact placeholder layer 114 may be formed of SiGe or another suitable material such as aluminum oxide (AlOx), titanium oxide (TiOx), aluminum nitride (AlNx), etc. In some embodiments, the backside contact placeholder layer 114 may have a width (in directions X and Y) in the range of 10 to 100 nm and a height (in direction Z) in the range of 10 to 30 nm deeper than the STI regions 112.

The bottom dummy gate layer 116 may be formed of amorphous silicon (a-Si), amorphous silicon germanium (a-SiGe) over a thin SiO2 or titanium nitride (TiN) layer, or another suitable material.

The spacer layer 118 may be formed of silicon boron carbide nitride (SiBCN) or another suitable material such as SiN, SiOC, silicon oxycarbonitride (SiOCN), etc. The spacer layer 118 may have a thickness in the range of 4 to 10 nm. The portions of the spacer layer 118 on sidewalls of the bottom dummy gate layer 116 provide gate spacers, while the portions of the spacer layer 118 on sidewalls of the sacrificial layers 108 provide inner spacers.

The source/drain regions 120 may be formed using an epitaxial growth process. The source/drain regions 120 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As), and antimony (Sb), and p-type dopants may be selected from a group of boron (B), boron fluoride (BF2), gallium (Ga), indium (In), and thallium (Tl). In some embodiments, the epitaxy process used to form the source/drain regions 120 comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) can be doped during deposition (in-situ doped) by adding dopants, such as n-type dopants (e.g., phosphorus or arsenic) or p-type dopants (e.g., boron or gallium), depending on the type of transistor to be formed. In some embodiments, the dopant concentration in the source/drain can range from 1×1019 cm−3 to 3×1021 cm−3, or preferably between 2×1020 cm−3 to 3×1021 cm−3. In some embodiments, the source/drain regions 120 may have widths (in direction Y) in the range of 10 to 100 nm, and may have heights (in direction Z) in the range of 20 to 100 nm.

The ILD layer 122 material may be formed of any suitable isolating material, such as SiO2, SiOC, SiON, etc. In some embodiments, the ILD layer 122 may have a height (in direction Z) matching that of the bottom dummy gate layer 116.

The semiconductor structure shown in FIGS. 1A-1D may be formed by depositing the nanosheet stack (e.g., the sacrificial layers 108 and the nanosheet channel layers 110) over the substrate 106. The nanosheet stack may then be patterned (e.g., using lithographic processing), followed by fill with material of the STI regions 112 and recess of the material of the STI regions 112 below the bottommost one of the sacrificial layers 108. The bottom dummy gate layer 116 is then patterned using a hard mask (not shown), followed by nanosheet recess and formation of the spacer layer 118 and nanosheet recess. An indent etch may be used to indent the sacrificial layers 108. After that, a backside contact placeholder cavity is patterned followed by formation of the backside contact placeholder layer 114. The source/drain regions 120 are then epitaxially grown, followed by deposition and planarization of the ILD layer 122.

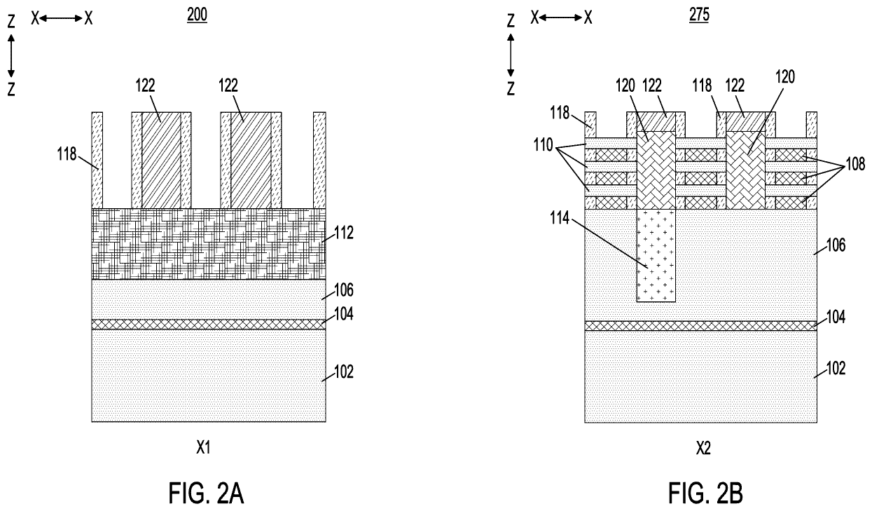

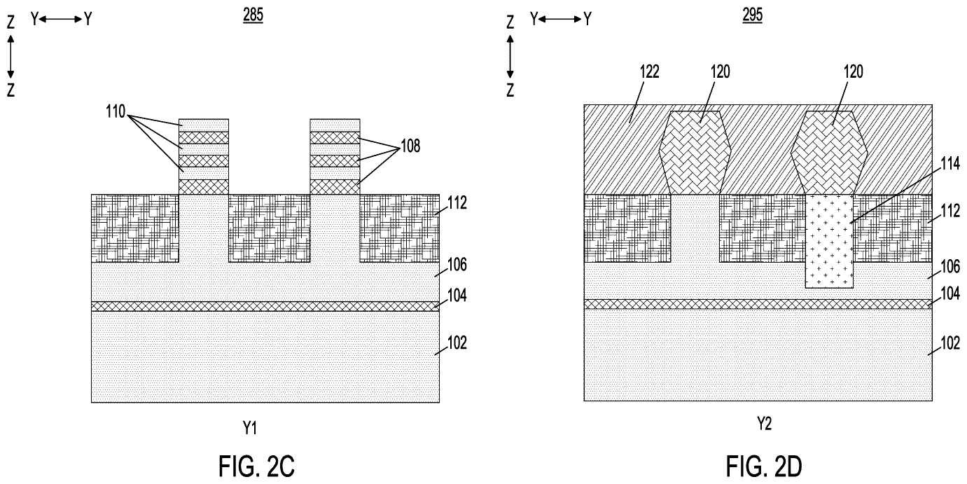

FIGS. 2A-2D show different views of the structure of FIGS. 1A-1D following removal of the bottom dummy gate layer 116. The cross-sectional view 200 of FIG. 2A is taken along the line A-A shown in the top-down view 199 of FIG. 1E. The cross-sectional view 275 of FIG. 2B is taken along the line B-B shown in the top-down view 199 of FIG. 1E. The cross-sectional view 285 of FIG. 2C is taken along the line C-C shown in the top-down view 199 of FIG. 1E. The cross-sectional view 295 of FIG. 2D is taken along the line D-D shown in the top-down view 199 of FIG. 1E. The bottom dummy gate layer 116 may be removed using any suitable etch processing.

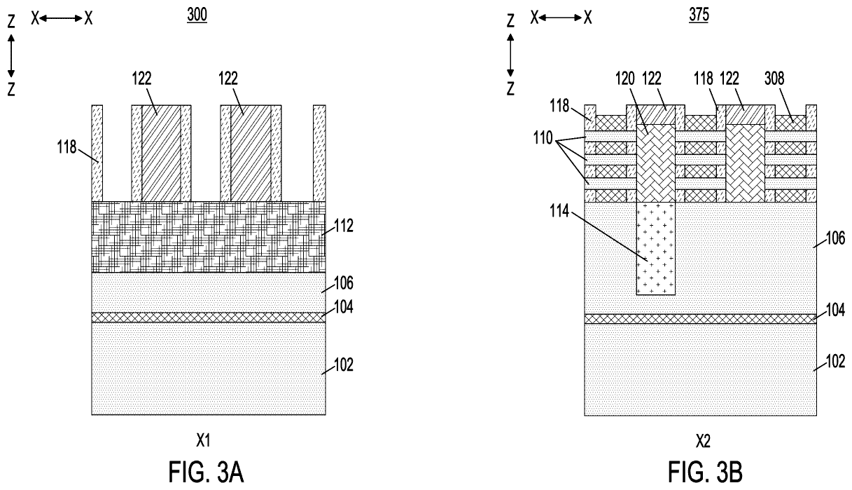

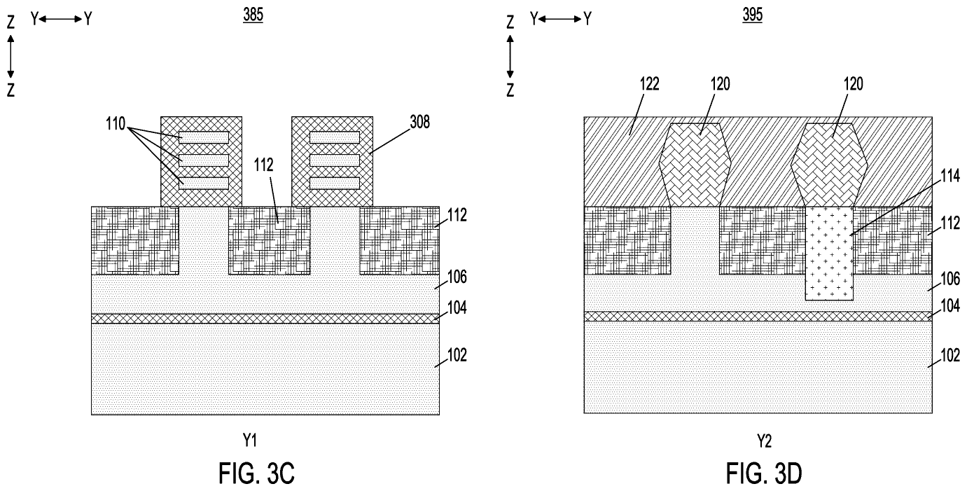

FIGS. 3A-3D show different views of the structure of FIGS. 2A-2D following growth of a conformal epitaxial layer 308 on the sacrificial layers 108, defining a gate extension region for the bottom transistors of the stacked transistor structure. The cross-sectional view 300 of FIG. 3A is taken along the line A-A shown in the top-down view 199 of FIG. 1E. The cross-sectional view 375 of FIG. 3B is taken along the line B-B shown in the top-down view 199 of FIG. 1E. The cross-sectional view 385 of FIG. 3C is taken along the line C-C shown in the top-down view 199 of FIG. 1E. The cross-sectional view 395 of FIG. 3D is taken along the line D-D shown in the top-down view 199 of FIG. 1E.

The conformal epitaxial layer 308 may be grown on the exposed nanosheet channel layers 110 and the sacrificial layers 108 to define the gate extension of the bottom transistors of the stacked transistor structure. The conformal epitaxial layer 308 may be formed of the same material as the sacrificial layers 108 (e.g., SiGe). The thickness of the gate extension may be in the range of 8 to 20 nm.

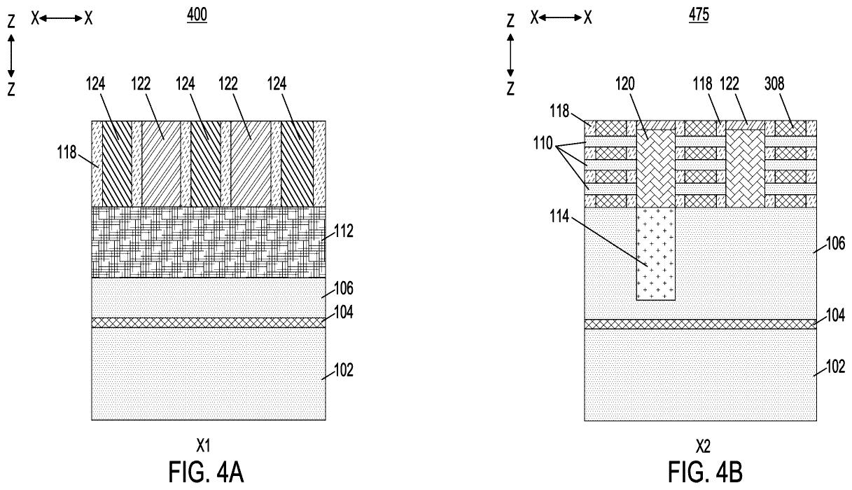

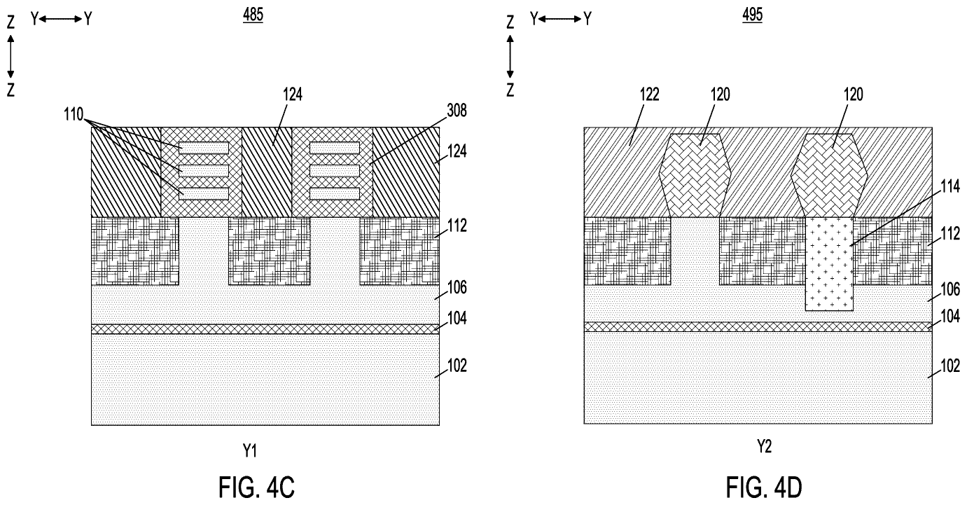

FIGS. 4A-4D show different views of the structure of FIGS. 3A-3D following formation of a self-aligned gate isolation layer 124. The cross-sectional view 400 of FIG. 4A is taken along the line A-A shown in the top-down view 199 of FIG. 1E. The cross-sectional view 475 of FIG. 4B is taken along the line B-B shown in the top-down view 199 of FIG. 1E. The cross-sectional view 485 of FIG. 4C is taken along the line C-C shown in the top-down view 199 of FIG. 1E. The cross-sectional view 495 of FIG. 4D is taken along the line D-D shown in the top-down view 199 of FIG. 1E.

The self-aligned gate isolation layer 124 may be formed by filling the structure with a dielectric material different than that used for the spacer layer 118 and the ILD layer 122. For example, the self-aligned gate isolation layer 124 may be formed of SiN, SiOCN, SiBCN, SiOC, SiC, AlNx, AlOx, etc. The dielectric material may then be planarized (e.g., using chemical mechanical planarization (CMP) or other suitable processing).

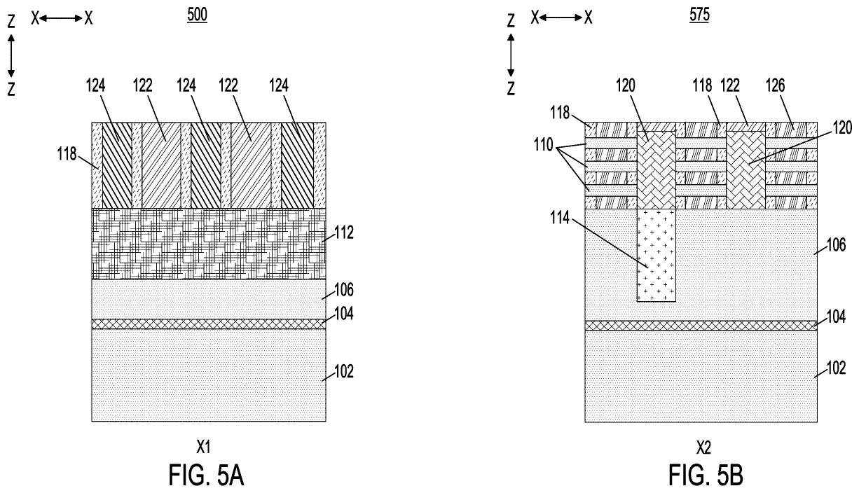

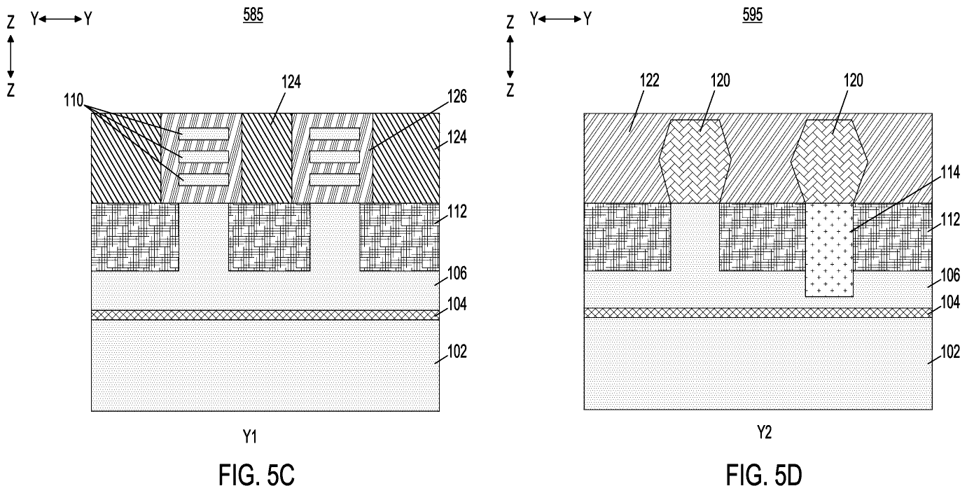

FIGS. 5A-5D show different views of the structure of FIGS. 4A-4D following formation of a gate stack 126 for the bottom transistors of the stacked transistor structure. The cross-sectional view 500 of FIG. 5A is taken along the line A-A shown in the top-down view 199 of FIG. 1E. The cross-sectional view 575 of FIG. 5B is taken along the line B-B shown in the top-down view 199 of FIG. 1E. The cross-sectional view 585 of FIG. 5C is taken along the line C-C shown in the top-down view 199 of FIG. 1E. The cross-sectional view 595 of FIG. 5D is taken along the line D-D shown in the top-down view 199 of FIG. 1E.

The gate stack 126 may be formed using replacement metal gate (RMG) processing, where the conformal epitaxial layer 308 is removed and then materials for the gate stack 126 are deposited. The gate stack 126 may include a gate dielectric and a gate conductor.

The gate dielectric may be conformally deposited in the structure and may be formed of a high-k material. Examples of high-k materials include, but are not limited to, metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric may have a uniform thickness in the range of 1 to 3 nm.

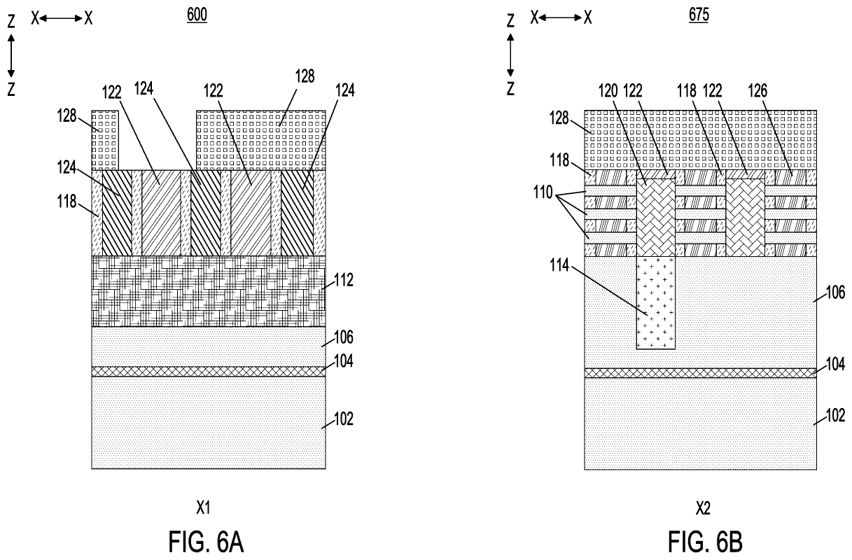

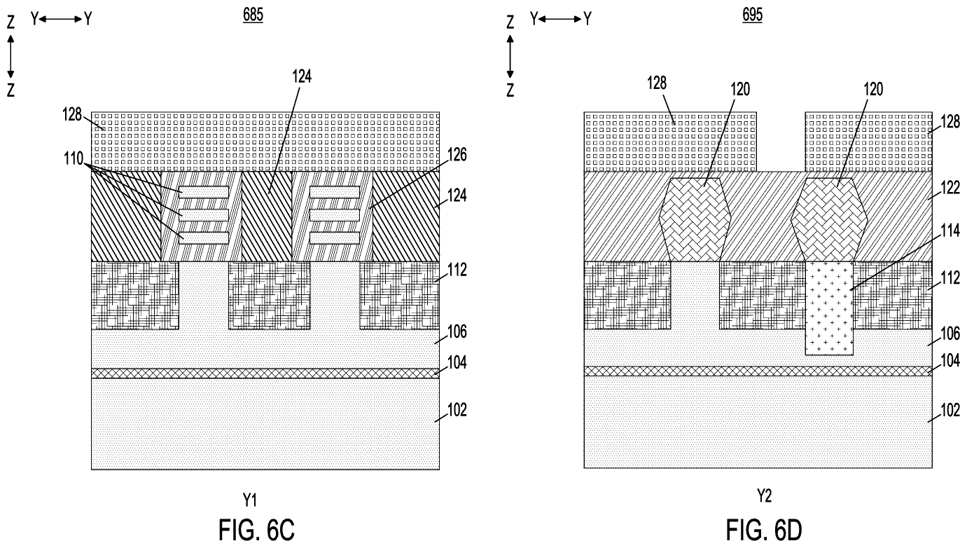

FIGS. 6A-6D show different views of the structure of FIGS. 5A-5D following patterning of an organic planarization layer (OPL) 128. The cross-sectional view 600 of FIG. 6A is taken along the line A-A shown in the top-down view 199 of FIG. 1E. The cross-sectional view 675 of FIG. 6B is taken along the line B-B shown in the top-down view 199 of FIG. 1E. The cross-sectional view 685 of FIG. 6C is taken along the line C-C shown in the top-down view 199 of FIG. 1E. The cross-sectional view 695 of FIG. 6D is taken along the line D-D shown in the top-down view 199 of FIG. 1E.

Material for the OPL 128 may be deposited over the structure, and then patterned using lithographic processing with a photoresist layer. The patterned OPL 128 has openings where backside contact placeholders for source/drain regions of top transistors of the stacked transistor structure will be formed.

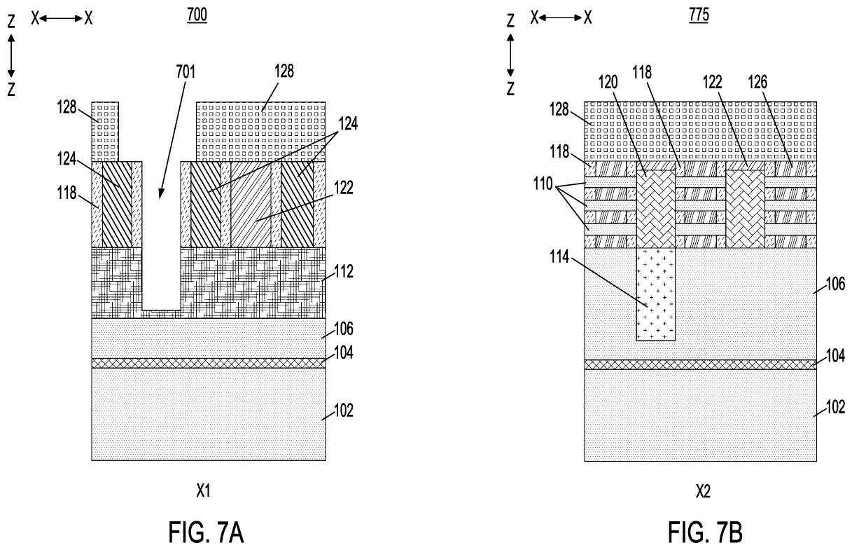

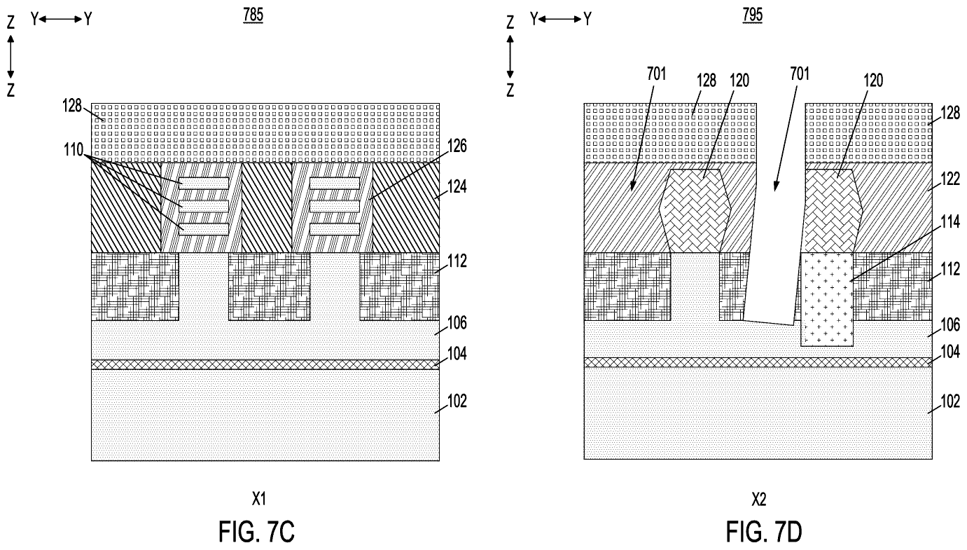

FIGS. 7A-7D show different views of the structure of FIGS. 6A-6D following selective etching of portions of the ILD layer 122 and the STI regions 112 exposed by the patterned OPL 128. The cross-sectional view 700 of FIG. 7A is taken along the line A-A shown in the top-down view 199 of FIG. 1E. The cross-sectional view 775 of FIG. 7B is taken along the line B-B shown in the top-down view 199 of FIG. 1E. The cross-sectional view 785 of FIG. 7C is taken along the line C-C shown in the top-down view 199 of FIG. 1E. The cross-sectional view 795 of FIG. 7D is taken along the line D-D shown in the top-down view 199 of FIG. 1E.

The exposed portion of the ILD layer 122 and STI regions 112 may be etched selectively to the spacer layer 118 and the self-aligned gate isolation layer 124, forming trench 701. The trench 701 is formed using an angled etch (e.g., reactive ion etching (RIE)), such that a bottom portion of the trench 701 is angled away from the backside contact placeholder layer 114, as shown in FIG. 7D.

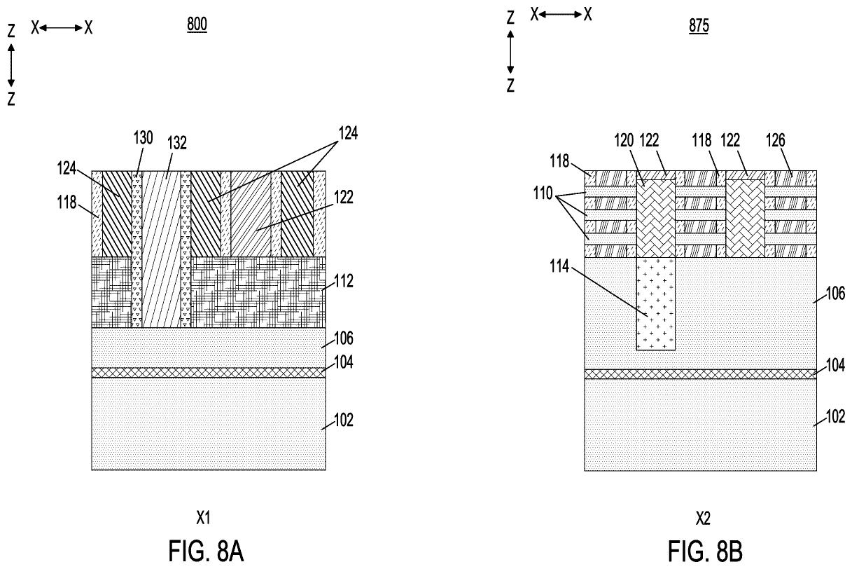

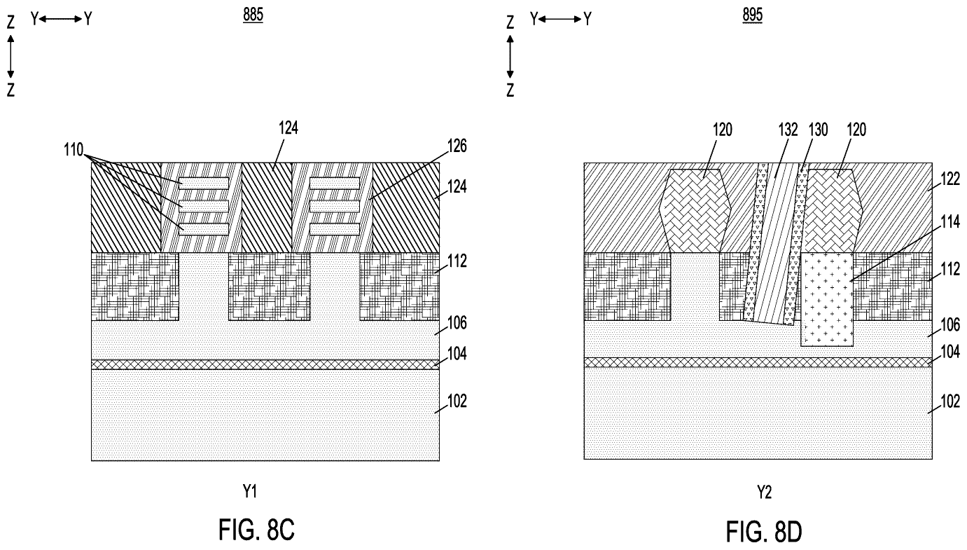

FIGS. 8A-8D show different views of the structure of FIGS. 7A-7D following lateral etching of portions of the spacer layer 118 and the STI regions 112, and formation of dielectric spacer layers 130 and a backside contact placeholder layer 132. The cross-sectional view 800 of FIG. 8A is taken along the line A-A shown in the top-down view 199 of FIG. 1E. The cross-sectional view 875 of FIG. 8B is taken along the line B-B shown in the top-down view 199 of FIG. 1E. The cross-sectional view 885 of FIG. 8C is taken along the line C-C shown in the top-down view 199 of FIG. 1E. The cross-sectional view 895 of FIG. 8D is taken along the line D-D shown in the top-down view 199 of FIG. 1E.

Exposed portions of the spacer layer 118 and the STI regions 112 are etched laterally utilizing an isotropic dry or wet etch process, for example, thereby widening the trench 701. In some embodiments, the depth of the lateral etch may be approximately the thickness of the spacer layer 118. The OPL 128 is removed, followed by formation of the dielectric spacer layers 130 on sidewalls of the trench 701. The material for the dielectric spacer layers 130 may be blanket deposited, followed by a directional etch which removes the material for the dielectric spacer layers 130 from the top surface of the structure and the bottom of the trench 701. The backside contact placeholder layer 132 is then formed to fill the remainder of the trench 701 (e.g., by overfilling the structure followed by planarization, such as a CMP process).

The dielectric spacer layers 130 may be formed of any suitable dielectric material such as SiN, SiBCN, SiOCN, SiOC, AlOx, AlNx, etc. The dielectric spacer layers 130 may have a thickness (in direction X) in the range of 4 to 10 nm. In some embodiments, the backside contact placeholder layer 132 may be formed of different material than the material of the backside contact placeholder layer 114. As a non-limiting example, the material of the backside contact placeholder layer 132 may be SiGe, and the material of the backside contact placeholder layer 114 may be polysilicon, or vice versa.

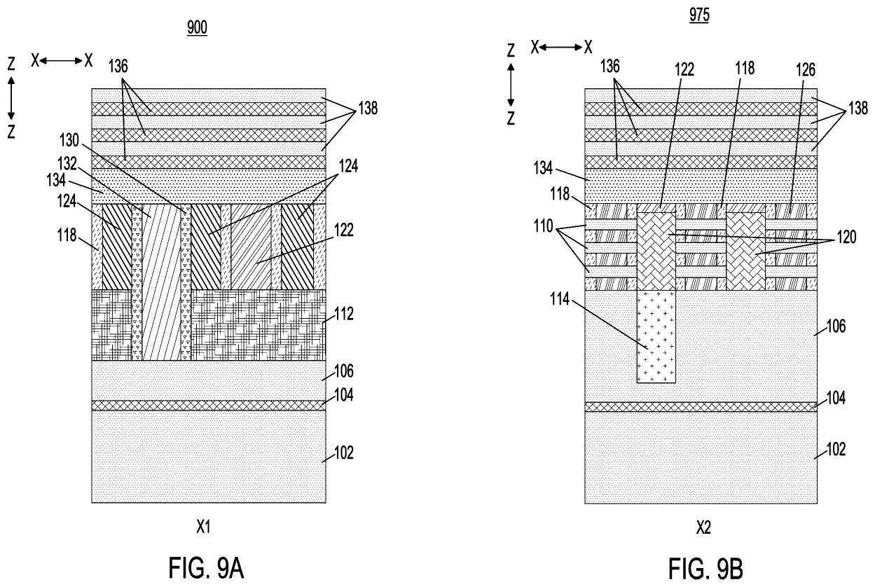

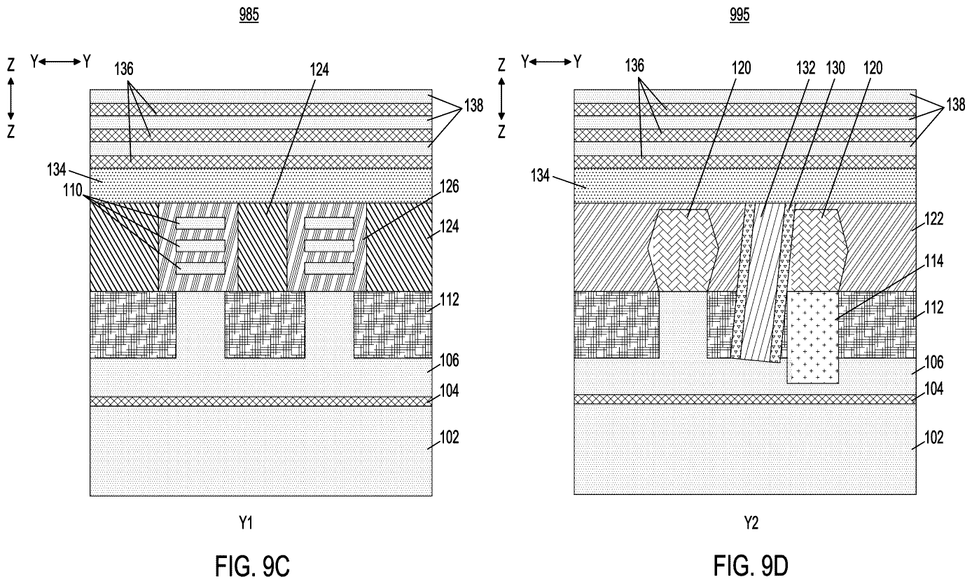

FIGS. 9A-9D show different views of the structure of FIGS. 8A-8D following bonding, via a bonding oxide 134, to another nanosheet stack for top transistors of the stacked transistor structure, the nanosheet stack including alternating sacrificial layers 136 and nanosheet channel layers 138. The cross-sectional view 900 of FIG. 9A is taken along the line A-A shown in the top-down view 199 of FIG. 1E. The cross-sectional view 975 of FIG. 9B is taken along the line B-B shown in the top-down view 199 of FIG. 1E. The cross-sectional view 985 of FIG. 9C is taken along the line C-C shown in the top-down view 199 of FIG. 1E. The cross-sectional view 995 of FIG. 9D is taken along the line D-D shown in the top-down view 199 of FIG. 1E.

Another Si wafer has the nanosheet stack of the sacrificial layers 136 and the nanosheet channel layers 138 formed on the top, followed by deposition of the bonding oxide 134 to the nanosheet stack of the sacrificial layers 136 and the nanosheet channel layers 138. The bonding oxide 134 is then bonded to the existing wafer through an oxide-to-oxide bonding process. After the wafer bonding, the Si wafer is removed leaving the nanosheet stack of the sacrificial layers 136 and the nanosheet channel layers 138 on the bonding oxide 134. The sacrificial layers 136 may be formed of similar materials and with similar sizing as the sacrificial layers 108. The nanosheet channel layers 138 may be formed of similar materials and with similar sizing as the nanosheet channel layers 110.

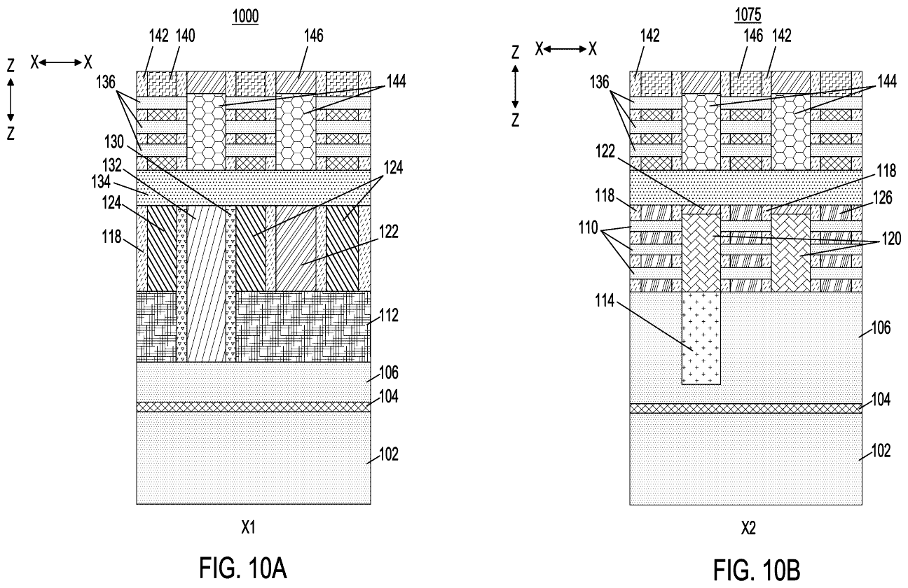

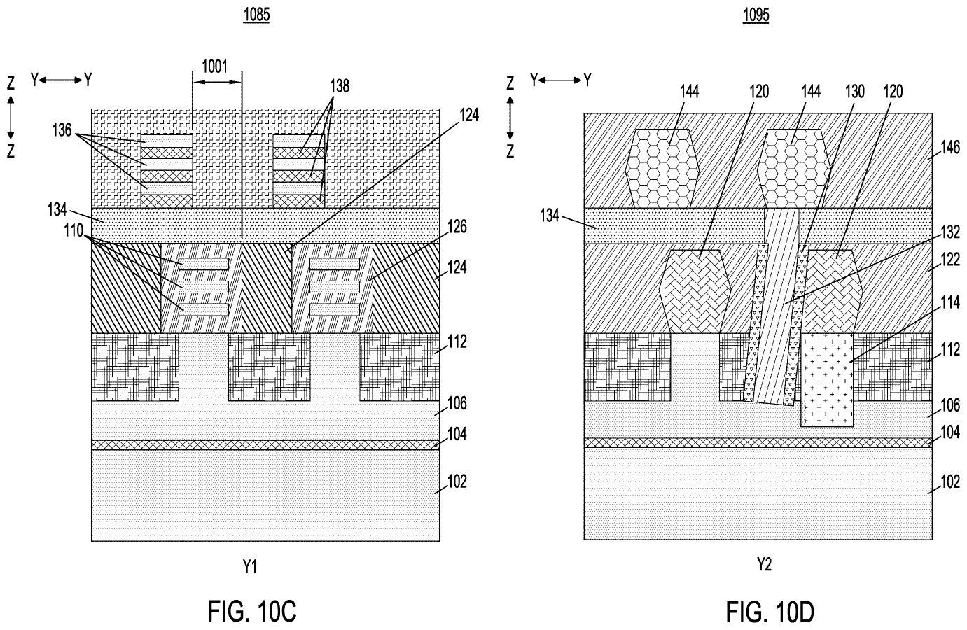

FIGS. 10A-10D show different views of the structure of FIGS. 9A-9D following formation of a top dummy gate layer 140, a spacer layer 142, source/drain regions 144 for the top transistors of the stacked transistor structure, and ILD layer 146. The cross-sectional view 1000 of FIG. 10A is taken along the line A-A shown in the top-down view 199 of FIG. 1E. The cross-sectional view 1075 of FIG. 10B is taken along the line B-B shown in the top-down view 199 of FIG. 1E. The cross-sectional view 1085 of FIG. 10C is taken along the line C-C shown in the top-down view 199 of FIG. 1E. The cross-sectional view 1095 of FIG. 10D is taken along the line D-D shown in the top-down view 199 of FIG. 1E.

The top dummy gate layer 140, spacer layer 142, source/drain regions 144 and ILD layer 146 may be formed using similar processing and with similar sizing and materials as the bottom dummy gate layer 116, the spacer layer 118, the source/drain regions 120 and the ILD layer 122, respectively. It should be noted that, in some embodiments, the top and bottom transistors of the stacked transistor structure have different polarities (e.g., the top transistors are n-type and the bottom transistors are p-type, or vice versa) and thus the source/drain regions 120 and source/drain regions 144 may utilize different dopants corresponding to such different polarities. As illustrated in the cross-sectional view 1085 of FIG. 10C, the nanosheet channel layers 138 for the top transistors of the stacked transistor structure are horizontally offset a lateral distance 1001 from the nanosheet channel layers 110 for the bottom transistors of the stacked transistor structure.

In some embodiments, the backside contact placeholder layer 132 is extended through the bonding oxide 134 prior to forming the source/drain regions 144. For example, a portion of the bonding oxide 134 above the source/drain regions 144 can be removed by patterning one or more masks with openings corresponding to the portion of the bonding oxide 134 that is to be removed, and performing an etching process (e.g., a dry etching process using a RIE or an ion beam etching (IBE) process, a wet chemical etch process, or a combination of these etching processes) to form openings in the bonding oxide 134 that expose the top surfaces of the source/drain regions 144. The opening are then filled with additional placeholder material to extend the backside contact placeholder layer 132 upwards.

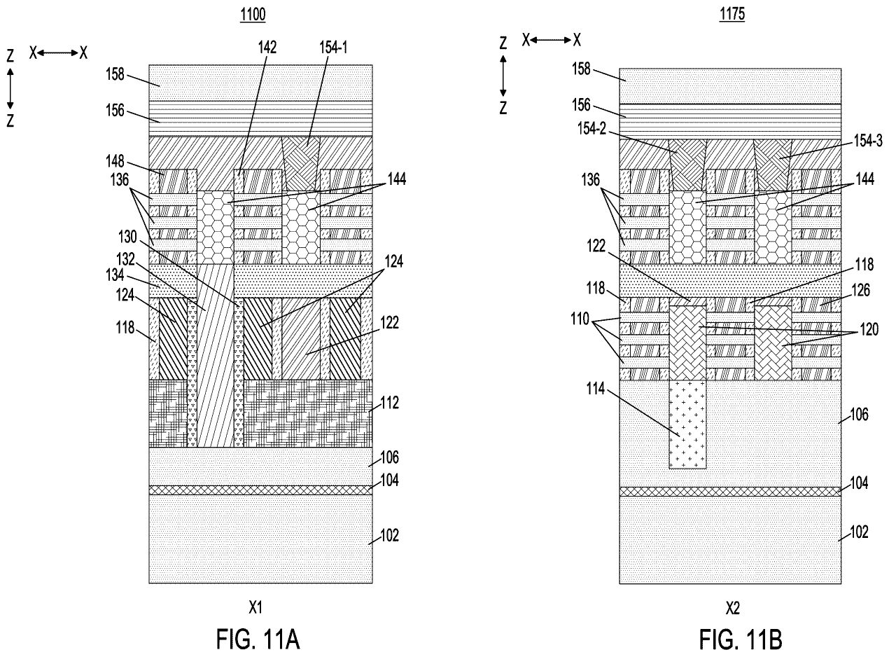

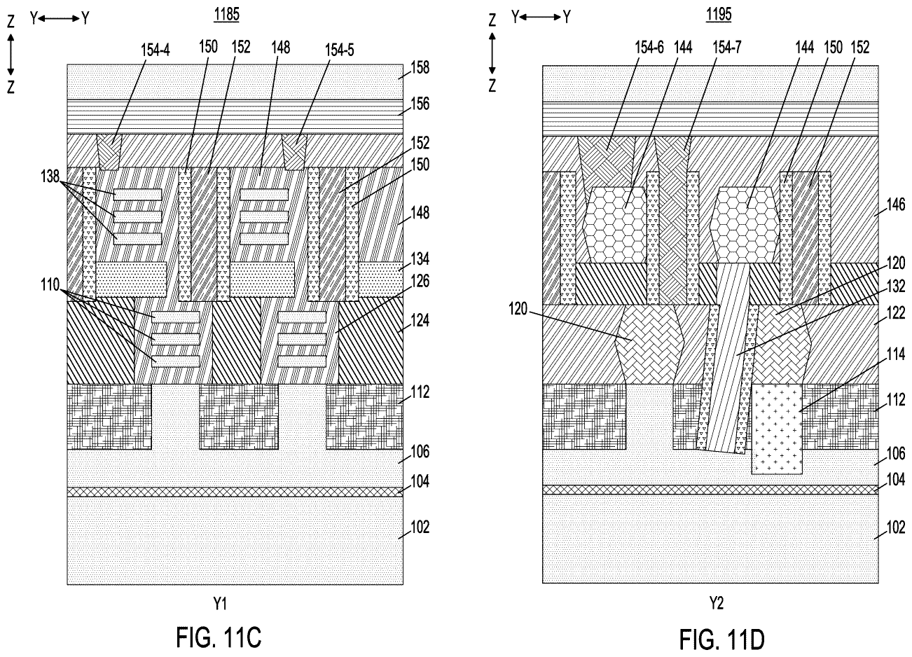

FIGS. 11A-11D show different views of the structure of FIGS. 10A-10D following formation of a gate stack 148 for the top transistors of the stacked transistor structure, a gate cut for the top transistors of the stacked transistor structure, and formation of dielectric spacer layers 150, frontside contact placeholder layers 152, frontside interconnects 154-1 through 154-7 (collectively “frontside interconnects 154”), a BEOL region 156, and bonding to a carrier wafer 158.

The cross-sectional view 1100 of FIG. 11A is taken along the line A-A shown in the top-down view 199 of FIG. 1E. The cross-sectional view 1175 of FIG. 11B is taken along the line B-B shown in the top-down view 199 of FIG. 1E. The cross-sectional view 1185 of FIG. 11C is taken along the line C-C shown in the top-down view 199 of FIG. 1E. The cross-sectional view 1195 of FIG. 11D is taken along the line D-D shown in the top-down view 199 of FIG. 1E.

The gate stack 148 may be formed of similar materials and with similar processing as the gate stack 126. The top dummy gate layer 140 is removed, followed by removal of the sacrificial layers 136, deposition of a gate dielectric layer of the gate stack 148, a reliability anneal, patterning of shared gate openings 1101 in the bonding oxide 134, and formation of the gate conductor of the gate stack 148 (e.g., a gate work function metal (WFM) layer and a gate metal layer).

The gate cut for the top transistors may be performed by patterning a mask over the structure, and then etching through exposed portions of the gate stack 148 and the bonding oxide 134 down to top surfaces of the source/drain regions 120. The dielectric spacer layers 150 are then formed using similar processing and with similar materials and sizing as that described above with respect to the dielectric spacer layers 130. The frontside contact placeholder layers 152 may be formed using similar processing as that described above with respect to the backside contact placeholder layer 132. The frontside contact placeholder layers 152 may be formed of a dielectric material such as SiO₂ or a low-k oxide.

The frontside interconnects 154 are formed by patterning a mask layer over the structure, and then etching exposed portions of the structure to form frontside interconnect trenches. Material (e.g., a conducting metal) for the frontside interconnects 154 is then deposited in the frontside interconnect trenches. The frontside interconnects 154-1, 154-2, 154-3 and 154-4 are connected to the source/drain regions 144 for the top transistors of the stacked transistor structure. The frontside interconnects 154-5 and 154-6 are connected to the gate stack 148 (which is electrically connected to the gate stack 126 via the above-described trenches formed through the bonding oxide 134). The frontside interconnect 154-7 is connected to the source/drain regions 120 of the bottom transistors of the stacked transistor structure. The frontside interconnect 154-7 provides for a self-aligned contact that partially wraps around the source/drain regions 120. The BEOL region 156 is then formed over the structure, followed by bonding to the carrier wafer 158. The carrier wafer 158 may be formed of Si or another suitable material.

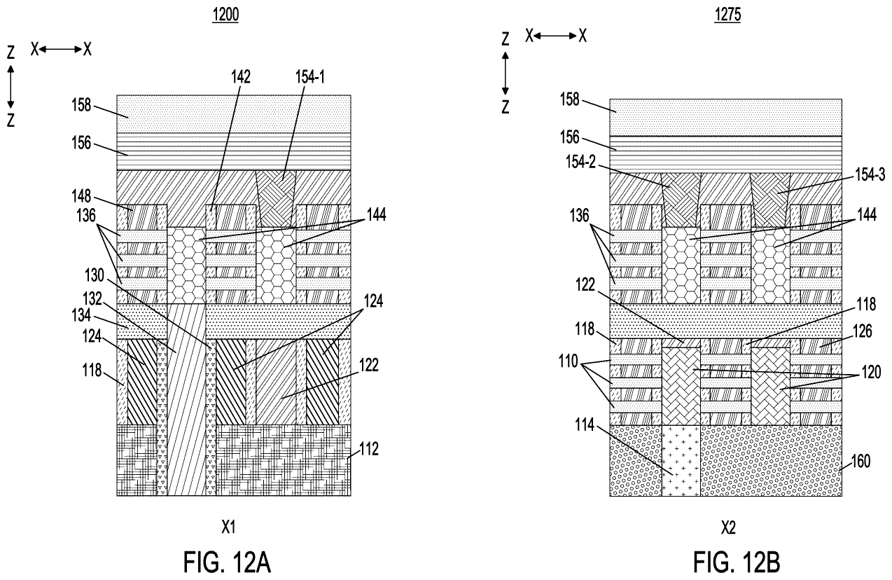

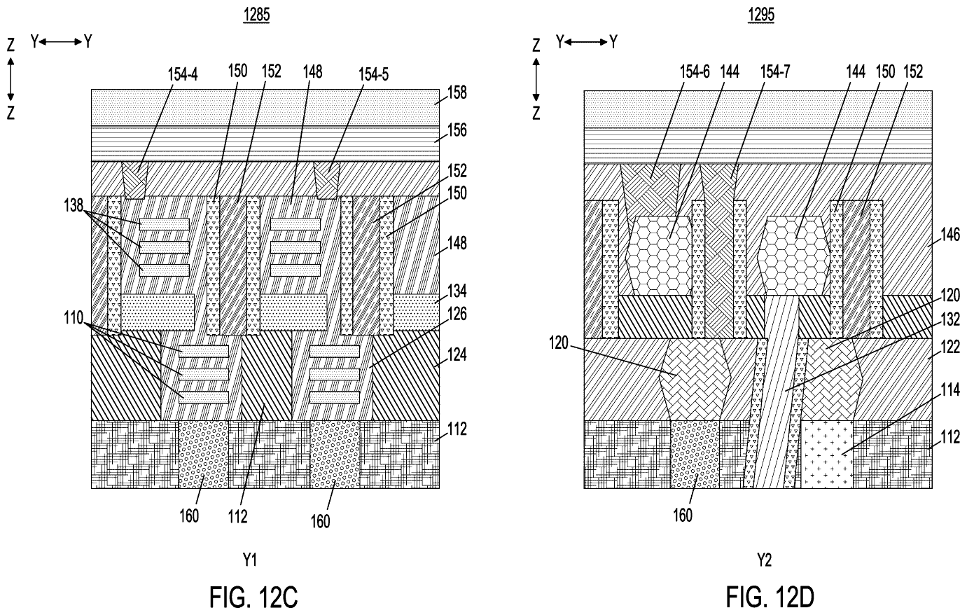

FIGS. 12A-12D show different views of the structure of FIGS. 11A-11D following wafer flip, removal of the substrate 102, the etch stop layer 104 and the substrate 106, and following formation of backside ILD layer 160. The cross-sectional view 1200 of FIG. 12A is taken along the line A-A shown in the top-down view 199 of FIG. 1E. The cross-sectional view 1275 of FIG. 12B is taken along the line B-B shown in the top-down view 199 of FIG. 1E. The cross-sectional view 1285 of FIG. 12C is taken along the line C-C shown in the top-down view 199 of FIG. 1E. The cross-sectional view 1295 of FIG. 12D is taken along the line D-D shown in the top-down view 199 of FIG. 1E.

A wafer flip may be performed using the carrier wafer 158, followed by etching to remove the substrate 102, the etch stop layer 104 and the substrate 106. The substrate 102, the etch stop layer 104 and the substrate 106 may be removed using any suitable etch processing. For example, a first RIE may be used to remove the substrate 102 (e.g., formed of Si), a second RIE may be used to remove the etch stop layer 104 (e.g., formed of SiGe), and a third RIE may be used to remove the substrate 106 (e.g., formed of Si). The backside contact placeholder layer 114, which may be formed of SiGe, remains as only the Si of the substrate 106 is removed by the third RIE. Material for the backside ILD layer 160 is then deposited and planarized (e.g., using CMP) to result in the backside ILD layer 160 as shown in FIGS. 12A-12D. The backside ILD layer 160 may be formed of any suitable isolating material, such as SiN, SiO₂, SiC, etc.

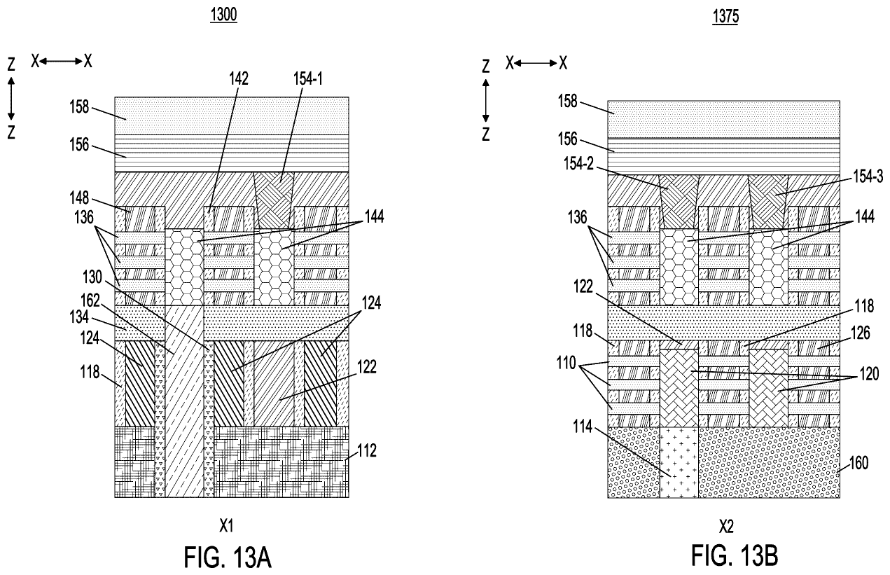

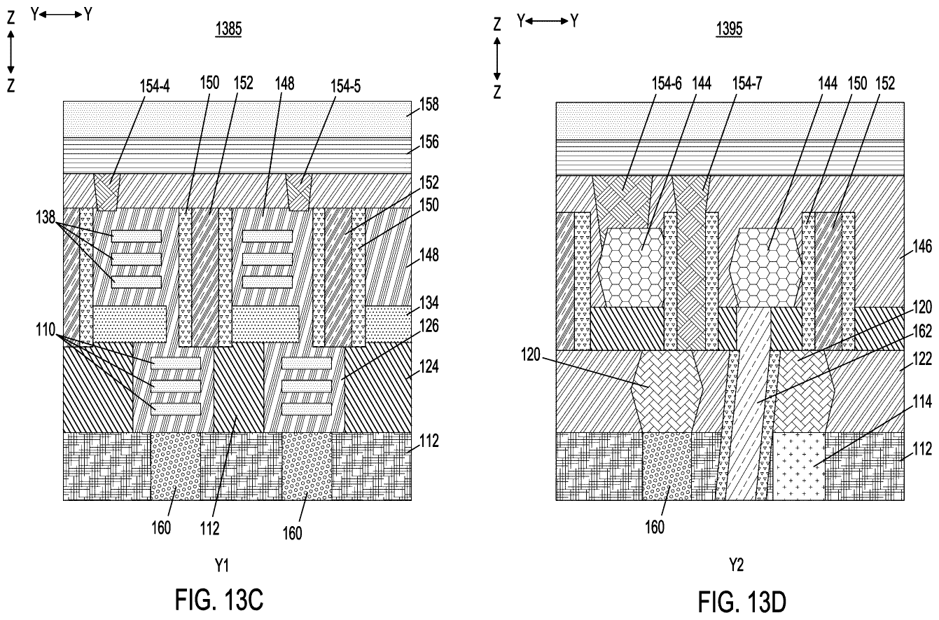

FIGS. 13A-13D show different views of the structure of FIGS. 12A-12D following removal of the backside contact placeholder layer 132 and formation of a backside contact 162 to the source/drain regions 144. The cross-sectional view 1300 of FIG. 13A is taken along the line A-A shown in the top-down view 199 of FIG. 1E. The cross-sectional view 1375 of FIG. 13B is taken along the line B-B shown in the top-down view 199 of FIG. 1E. The cross-sectional view 1385 of FIG. 13C is taken along the line C-C shown in the top-down view 199 of FIG. 1E. The cross-sectional view 1395 of FIG. 13D is taken along the line D-D shown in the top-down view 199 of FIG. 1E.

The backside contact placeholder layer 132 is removed using any suitable etch processing. A silicide liner (not shown) may be formed (e.g., on the exposed portions of the bottom surface of the source/drain regions 144). The silicide liner may be formed of nickel (Ni), titanium (Ti), a nickel-platinum alloy (NiPt), etc., and may have a height (in direction Z) in the range of 1 to 10 nm. The backside contact 162 is then patterned and formed as shown. The backside contact 162 is angled away from the backside contact placeholder layer 132, as shown in FIG. 13D.

The backside contact 162 can comprise one or more metal layers including, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD) sputtering and/or plating, followed by a planarization process such as, CMP to remove excess portions of the metal layers.

FIGS. 11A-11D show different views of the structure of FIGS. 10A-10D following formation of a gate stack 148 for the top transistors of the stacked transistor structure, a gate cut for the top transistors of the stacked transistor structure, and formation of dielectric spacer layers 150, frontside contact placeholder layers 152, frontside interconnects 154-1 through 154-7 (collectively “frontside interconnects 154”), a BEOL region 156, and bonding to a carrier wafer 158. The cross-sectional view 1100 of FIG. 11A is taken along the line A-A shown in the top-down view 199 of FIG. 1E. The cross-sectional view 1175 of FIG. 11B is taken along the line B-B shown in the top-down view 199 of FIG. 1E. The cross-sectional view 1185 of FIG. 11C is taken along the line C-C shown in the top-down view 199 of FIG. 1E. The cross-sectional view 1195 of FIG. 11D is taken along the line D-D shown in the top-down view 199 of FIG. 1E.

The gate stack 148 may be formed of similar materials and with similar processing as the gate stack 126. The top dummy gate layer 140 is removed, followed by removal of the sacrificial layers 136, deposition of a gate dielectric layer of the gate stack 148, a reliability anneal, patterning of shared gate openings 1101 in the bonding oxide 134, and formation of the gate conductor of the gate stack 148 (e.g., a gate WFM layer and a gate metal layer).

The gate cut for the top transistors may be performed by patterning a mask over the structure, and then etching through exposed portions of the gate stack 148 and the bonding oxide 134 down to top surfaces of the source/drain regions 144. The dielectric spacer layers 150 are then formed using similar processing and with similar materials and sizing as that described above with respect to the dielectric spacer layers 130. The frontside contact placeholder layers 152 may be formed using similar processing as that described above with respect to the backside contact placeholder layer 132. The frontside contact placeholder layers 152 may be formed of a dielectric material such as SiO2 or a low-k oxide.

The frontside interconnects 154 are formed by patterning a mask layer over the structure, and then etching exposed portions of the structure to form frontside interconnect trenches. Material (e.g., a conducting metal) for the frontside interconnects 154 is then deposited in the frontside interconnect trenches. The frontside interconnects 154-1, 154-2, 154-3 and 154-4 are connected to the source/drain regions 144 for the top transistors of the stacked transistor structure. The frontside interconnects 154-5 and 154-6 are connected to the gate stack 148 (which is electrically connected to the gate stack 126 via the above-described trenches formed through the bonding oxide 134). The frontside interconnect 154-7 is connected to the source/drain regions 120 of the bottom transistors of the stacked transistor structure. The frontside interconnect 154-7 provides for a self-aligned contact that partially wraps around the source/drain regions 120. The BEOL region 156 is then formed over the structure, followed by bonding to the carrier wafer 158. The carrier wafer 158 may be formed of Si or another suitable material.

FIGS. 12A-12D show different views of the structure of FIGS. 11A-11D following wafer flip, removal of the substrate 102, the etch stop layer 104 and the substrate 106, and following formation of backside ILD layer 160. The cross-sectional view 1200 of FIG. 12A is taken along the line A-A shown in the top-down view 199 of FIG. 1E. The cross-sectional view 1275 of FIG. 12B is taken along the line B-B shown in the top-down view 199 of FIG. 1E. The cross-sectional view 1285 of FIG. 12C is taken along the line C-C shown in the top-down view 199 of FIG. 1E. The cross-sectional view 1295 of FIG. 12D is taken along the line D-D shown in the top-down view 199 of FIG. 1E.

A wafer flip may be performed using the carrier wafer 158, followed by etching to remove the substrate 102, the etch stop layer 104 and the substrate 106. The substrate 102, the etch stop layer 104 and the substrate 106 may be removed using any suitable etch processing. For example, a first RIE may be used to remove the substrate 102 (e.g., formed of Si), a second RIE may be used to remove the etch stop layer 104 (e.g., formed of SiGe), and a third RIE may be used to remove the substrate 106 (e.g., formed of Si). The backside contact placeholder layer 114, which may be formed of SiGe, remains as only the Si of the substrate 106 is removed by the third RIE. Material for the backside ILD layer 160 is then deposited and planarized (e.g., using CMP) to result in the backside ILD layer 160 as shown in FIGS. 12A-1D. The backside ILD layer 160 may be formed of any suitable isolating material, such as SiN, SiO2, SiC, etc.

FIGS. 13A-13D show different views of the structure of FIGS. 12A-12D following removal of the backside contact placeholder layer 132 and formation of a backside contact 162 to the source/drain regions 144. The cross-sectional view 1300 of FIG. 13A is taken along the line A-A shown in the top-down view 199 of FIG. 1E. The cross-sectional view 1375 of FIG. 13B is taken along the line B-B shown in the top-down view 199 of FIG. 1E. The cross-sectional view 1385 of FIG. 13C is taken along the line C-C shown in the top-down view 199 of FIG. 1E. The cross-sectional view 1395 of FIG. 13D is taken along the line D-D shown in the top-down view 199 of FIG. 1E.

The backside contact placeholder layer 132 is removed using any suitable etch processing. A silicide liner (not shown) may be formed (e.g., on the exposed portions of the bottom surface of the source/drain regions 144). The silicide liner may be formed of nickel (Ni), titanium (Ti), a nickel-platinum alloy (NiPt), etc., and may have a height (in direction Z) in the range of 1 to 10 nm. The backside contact 162 is then patterned and formed as shown. The backside contact 162 is angled away from the backside contact placeholder layer 132, as shown in FIG. 13D.

The backside contact 162 can comprise one or more metal layers including, for example, a silicide layer, such as Ni, Ti, NiPt, etc., a metal adhesion layer, such as TiN, and a conductive metal fill layer, such as W, Al, Co, Ru, etc. The backside contact 162 can be deposited using, for example, a deposition technique such as CVD, plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), sputtering and/or plating, followed by a planarization process such as CMP to remove excess portions of the metal layers.

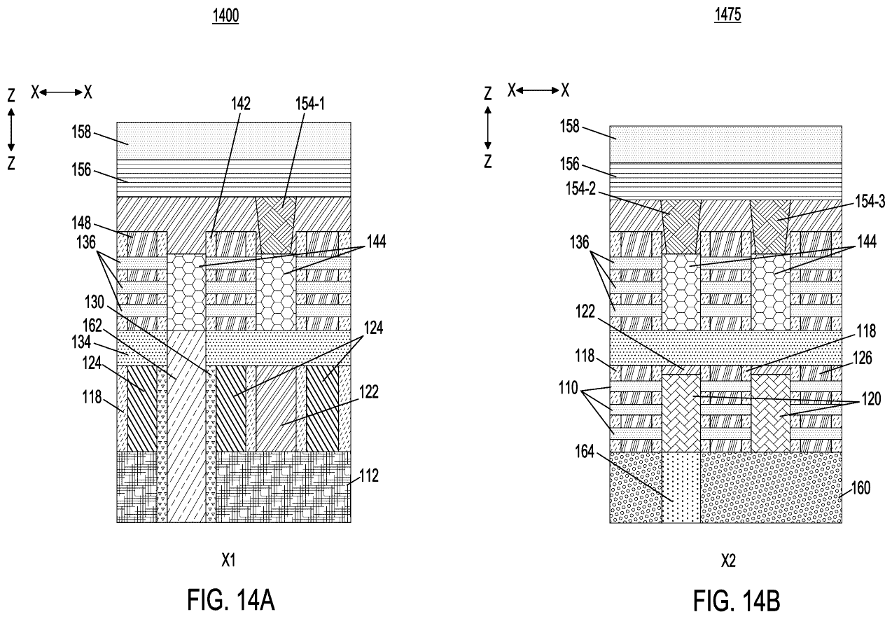

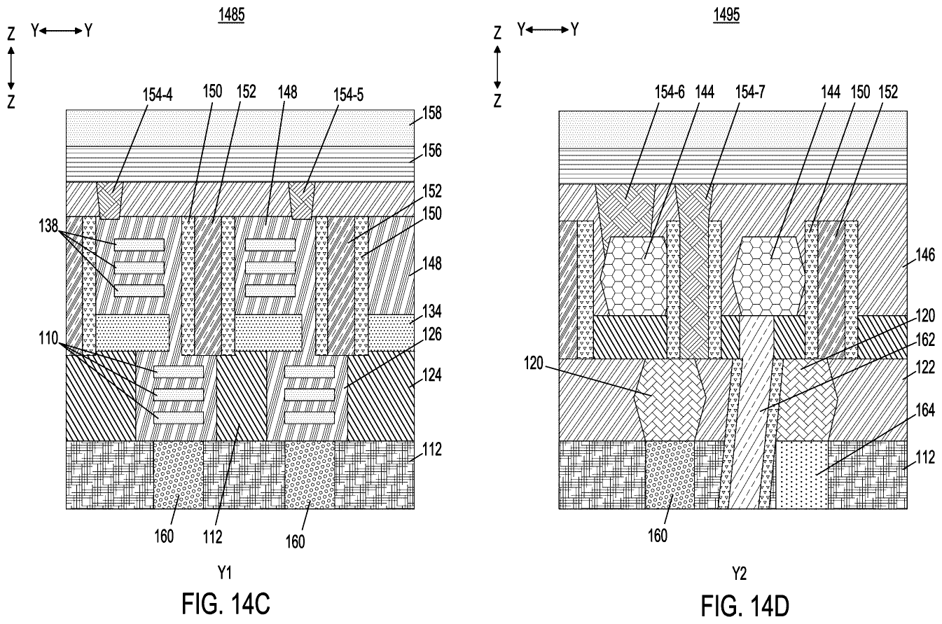

FIGS. 14A-14D show different views of the structure of FIGS. 13A-13D following selective removal of the backside contact placeholder layer 114 and the formation of a backside contact 164 to the source/drain regions 120 of the bottom transistors of the stacked transistor structure. The cross-sectional view 1400 of FIG. 14A is taken along the line A-A shown in the top-down view 199 of FIG. 1E. The cross-sectional view 1475 of FIG. 14B is taken along the line B-B shown in the top-down view 199 of FIG. 1E. The cross-sectional view 1485 of FIG. 14C is taken along the line C-C shown in the top-down view 199 of FIG. 1E. The cross-sectional view 1495 of FIG. 14D is taken along the line D-D shown in the top-down view 199 of FIG. 1E.

The backside contact placeholder layer 114 is removed using any suitable etch processing. Another silicide liner (not shown) may be formed (e.g., on the exposed portions of the bottom surface of the source/drain regions 120). The backside contact 164 is then patterned and formed as shown. The silicide liner corresponding to the backside contact 164 may be formed using similar processing and sizing as for the silicide liner corresponding to the backside contact 162. In some embodiments, the silicide liner corresponding to the backside contact 164 may be formed of a different silicide material than the silicide liner corresponding to the backside contact 162. As a non-limiting example, the silicide liner corresponding to the backside contact 162 may be formed of Ti, and the silicide liner corresponding to the backside contact 164 may be formed of NiPt.

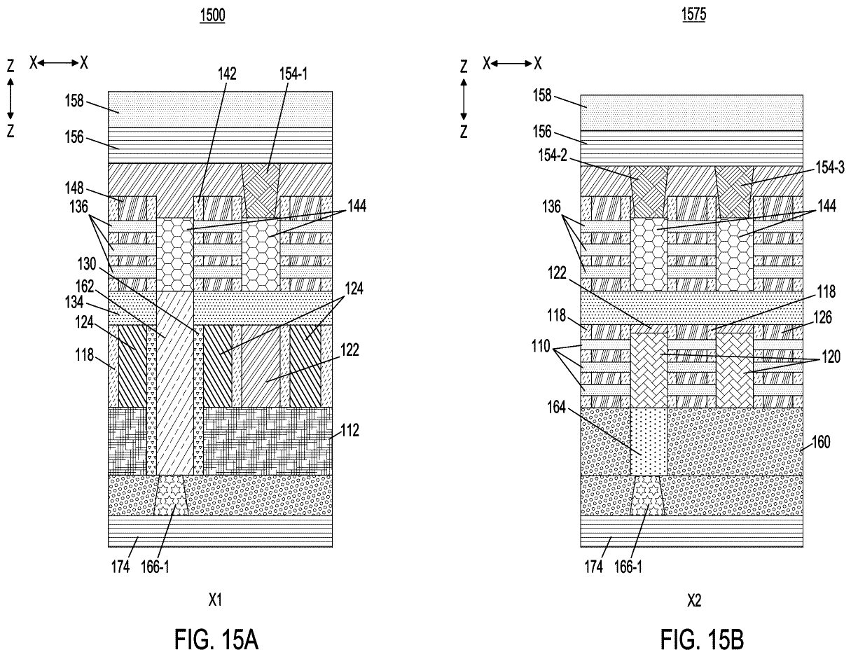

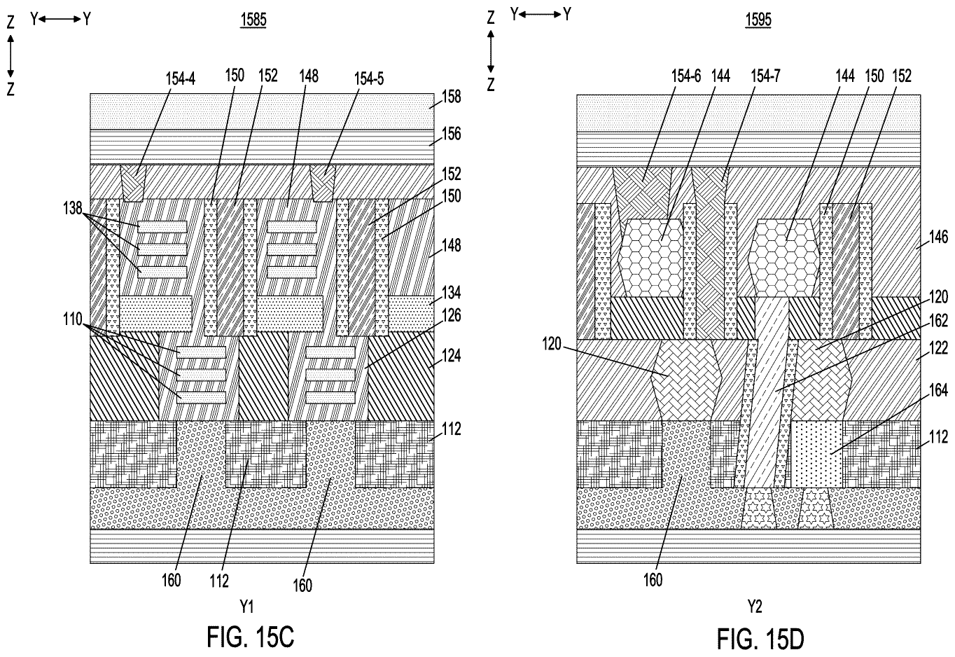

FIGS. 15A-15D show different views of the structure of FIGS. 14A-14D following formation of backside interconnect layer 174 including backside vias 166-1 and 166-2. The cross-sectional view 1500 of FIG. 15A is taken along the line A-A shown in the top-down view 199 of FIG. 1E. The cross-sectional view 1575 of FIG. 15B is taken along the line B-B shown in the top-down view 199 of FIG. 1E. The cross-sectional view 1585 of FIG. 15C is taken along the line C-C shown in the top-down view 199 of FIG. 1E. The cross-sectional view 1595 of FIG. 15D is taken along the line D-D shown in the top-down view 199 of FIG. 1E.

In some embodiments, additional dielectric material can be deposited to extend the backside ILD layer 160 downwards, and the backside vias 166-1 and 166-2 can be formed through the backside ILD layer 160. The backside interconnect layer 174 can be formed on the backside ILD layer 160 and can include various backside interconnect structures, such as power delivery network structures including, but not limited to, interconnects in a power supply path from voltage regulator modules (VRMs) to circuits. The interconnect structures can comprise, for example, power and ground planes in circuit boards, cables, connectors, and capacitors associated with a power supply. Backside power delivery prevents BEOL routing congestion resulting in improved power performance benefits. In some embodiments, the backside interconnect layer 174 can alternatively or additionally be used for signal routing including power and/or clock signals as non-limiting examples.

The backside via 166-1 connects the backside contact 162 to at least one interconnect structure of the backside interconnect layer 174, and the backside via 166-2 connects the backside contact 164 to at least one other interconnect structure of the backside interconnect layer 174, as shown in FIG. 15D. The process and materials used for forming the backside interconnect layer 174 and the backside vias 166-1 and 166-2 can be similar to those used to form the backside contacts 162 and 164, for example.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductor (CMOS) transistors, metal-oxide-semiconductor field-effect transistors (MOSFETs), and/or fin field-effect transistors (FinFETs). By way of non-limiting example, the semiconductor devices can include, but are not limited to, CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In an illustrative embodiment, a semiconductor device includes a first transistor including a first set of one or more channels and a second transistor vertically stacked over the first transistor, where the second transistor includes a second set of one or more channels. The semiconductor device also includes a first contact extending from a first side of the semiconductor structure to a first source/drain region of the first transistor, and a second contact extending from the first side of the semiconductor structure to a second source/drain region of the second transistor, where the second contact is angled away from the first contact.

In embodiments, the second contact may include a straight portion that contacts a bottom side of the second source/drain region.

In embodiments, the second contact may include an angled portion below the straight portion.

In embodiments, the semiconductor structure may further include a dielectric liner between the second contact and the first source/drain region.

In embodiments, the second contact may include a straight cross-sectional profile along a direction that is perpendicular to gate structures of the second transistor.

In embodiments, the second contact may include an angled cross-sectional profile along a direction that is parallel to the gate structures of the second transistor.

In embodiments, the semiconductor structure may further include a first via connected to a bottom surface of the first contact, and a second via connected to a bottom surface of the second contact, where the second via is adjacent to the first via.

In embodiments, the first via and the second via may be separated by an interlayer dielectric layer.

In embodiments, the first via and the second via may be connected to respective backside interconnect structures.

In another embodiment, a semiconductor device includes a first transistor comprising a first set of one or more channels, a second transistor vertically stacked over the first transistor, the second transistor comprising a second set of one or more channels, where the second set of channels of the second transistor is horizontally offset from the first set of channels of the first transistor. The semiconductor device also includes a first contact extending from a first side of the semiconductor structure to a first source/drain region of the first transistor, and a second contact extending from the first side of the semiconductor structure to a second source/drain region of the second transistor, where the second contact is angled away from the first contact.

In embodiments, the second contact may include a straight portion that contacts a bottom side of the second source/drain region.

In embodiments, the second contact may include an angled portion below the straight portion.

In embodiments, the semiconductor structure may further include a dielectric liner between the second contact and the first source/drain region.

In embodiments, the second contact may include a straight cross-sectional profile along a direction that is perpendicular to gate structures of the second transistor.

In embodiments, the second contact may include an angled cross-sectional profile along a direction that is parallel to the gate structures of the second transistor.

In embodiments, the semiconductor structure may further include a first via connected to a bottom surface of the first contact, and a second via connected to a bottom surface of the second contact, where the second via is adjacent to the first via.

In yet another embodiment, a method includes forming a first transistor of a semiconductor structure comprising a first set of one or more channels, forming a second transistor vertically stacked over the first transistor, the second transistor comprising a second set of one or more channels, and forming a first contact extending from a first side of the semiconductor structure to a first source/drain region of the first transistor. The method also includes forming a second contact extending from the first side of the semiconductor structure to a second source/drain region of the second transistor, where the second contact is angled away from the first contact.

In embodiments, forming the first contact may include forming a first contact placeholder comprising a first placeholder material, and replacing the first contact placeholder to form the first contact.

In embodiments, forming the second contact may include forming a second contact placeholder comprising a second placeholder material, and replacing the second contact placeholder to form the second contact.

In embodiments, the second placeholder material may be different than the first placeholder material.

Conventional techniques for designing and fabricating stacked transistor structures with shifted channels often require complex BEOL patterning schemes for backside contacts for top and bottom transistors. Without in any way limiting the scope, interpretation, or application of the claims appearing below, a technical effect of one or more of the example embodiments disclosed herein can effectively mitigating potential shorts between backside contacts by forming a first backside contact for a top transistor that is angled away from a second backside contact for a bottom transistor. The angled backside contact design allows for clear separation between backside vias connected to the first and the second backside contacts, thus avoiding the need for the complex BEOL patterning schemes used by conventional techniques.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first transistor comprising a first set of one or more channels;
a second transistor vertically stacked over the first transistor, the second transistor comprising a second set of one or more channels;
a first contact extending from a first side of the semiconductor structure to a first source/drain region of the first transistor; and
a second contact extending from the first side of the semiconductor structure to a second source/drain region of the second transistor, wherein the second contact is angled away from the first contact.

2. The semiconductor structure of claim 1, wherein the second contact comprises a straight portion that contacts a bottom side of the second source/drain region.

3. The semiconductor structure of claim 2, wherein the second contact comprises an angled portion below the straight portion.

4. The semiconductor structure of claim 1, further comprising:
a dielectric liner between the second contact and the first source/drain region.

5. The semiconductor structure of claim 1, wherein the second contact comprises a straight cross-sectional profile along a direction that is perpendicular to gate structures of the second transistor.

6. The semiconductor structure of claim 5, wherein the second contact comprises an angled cross-sectional profile along a direction that is parallel to the gate structures of the second transistor.

7. The semiconductor structure of claim 1, further comprising:
a first via connected to a bottom surface of the first contact; and
a second via connected to a bottom surface of the second contact, wherein the second via is adjacent to the first via.

8. The semiconductor structure of claim 7, wherein the first via and the second via are separated by an interlayer dielectric layer.

9. The semiconductor structure of claim 8, wherein the first via and the second via are connected to respective backside interconnect structures.

10. A semiconductor structure, comprising:
a first transistor comprising a first set of one or more channels;
a second transistor vertically stacked over the first transistor, the second transistor comprising a second set of one or more channels, wherein the second set of channels of the second transistor is horizontally offset from the first set of channels of the first transistor;
a first contact extending from a first side of the semiconductor structure to a first source/drain region of the first transistor; and
a second contact extending from the first side of the semiconductor structure to a second source/drain region of the second transistor, wherein the second contact is angled away from the first contact.

11. The semiconductor structure of claim 10, wherein the second contact comprises a straight portion that contacts a bottom side of the second source/drain region.

12. The semiconductor structure of claim 11, wherein the second contact comprises an angled portion below the straight portion.

13. The semiconductor structure of claim 10, further comprising:
a dielectric liner between the second contact and the first source/drain region.

14. The semiconductor structure of claim 10, wherein the second contact comprises a straight cross-sectional profile along a direction that is perpendicular to gate structures of the second transistor.

15. The semiconductor structure of claim 14, wherein the second contact comprises an angled cross-sectional profile along a direction that is parallel to the gate structures of the second transistor.

16. The semiconductor structure of claim 10, further comprising:
a first via connected to a bottom surface of the first contact; and
a second via connected to a bottom surface of the second contact, wherein the second via is adjacent to the first via.

17. A method comprising:
forming a first transistor of a semiconductor structure comprising a first set of one or more channels;
forming a second transistor vertically stacked over the first transistor, the second transistor comprising a second set of one or more channels;
forming a first contact extending from a first side of the semiconductor structure to a first source/drain region of the first transistor; and
forming a second contact extending from the first side of the semiconductor structure to a second source/drain region of the second transistor, wherein the second contact is angled away from the first contact.

18. The method of claim 17, wherein forming the first contact comprises:
forming a first contact placeholder comprising a first placeholder material; and
replacing the first contact placeholder to form the first contact.

19. The method of claim 18, wherein forming the second contact comprises:
forming a second contact placeholder comprising a second placeholder material; and
replacing the second contact placeholder to form the second contact.

20. The method of claim 19, wherein the second placeholder material is different than the first placeholder material.
